(19) United States
(12) Patent Application Publication
(10) Pub. No.: US 2025/0005238 A1
(43) Pub. Date: Jan. 2, 2025

(54) PERFORMANT UNCERTAINTY METHODS FOR INPUT-OUTPUT MODELS

(71) Applicant: INDIGO AG, INC., Charlestown, MA (US)

(72) Inventors: Keith Frederick Ma, Cambridge, MA (US); Brian D. Segal, Washington, DC (US); Katherine O'Leary, Providence, RI (US)

(21) Appl. No.: 18/759,220

(22) Filed: Jun. 28, 2024

Related U.S. Application Data
(60) Provisional application No. 63/523,775, filed on Jun. 28, 2023.

(51) Int. Cl. G06F 30/27; G06Q 50/02

(52) U.S. Cl. CPC G06F 30/27; G06Q 50/02

(57) ABSTRACT

Systems and methods for determining an impact value for an event are disclosed. A method comprises ingesting one or more ingesting one or more agronomic event, decomposing the one or more agronomic event into a series of activities, translating the series of activities into a corresponding set of reference activities, reading a precomputed reference matrix, wherein the precomputed reference matrix comprises a plurality of precalculated impact values corresponding to the reference activity, computing an impact value for each activity of the series of activities, wherein said computing comprises determining a weight for each of the plurality of values of the reference matrix, aggregating an impact value for each agronomic event to determine a total impact value, based on the determined weight and the precomputed reference matrix, and outputting the aggregated impact value.

### CROSS REFERENCE TO RELATED APPLICATIONS

This application claims the benefit of U.S. Provisional Application No. 63/523,775, filed Jun. 28, 2023, which is hereby incorporated by reference in its entirety.

### FIELD OF DISCLOSURE

Embodiments of the present disclosure relate generally to input-output models, and in particular, to methods and systems for calculating uncertainty for input-output models.

### BACKGROUND

Measuring and predicting the environmental impact of agronomic activities, such as various farming or forestry operations, are crucial elements in managing sustainable agriculture systems and meeting environmental regulations. This is particularly important in the context of climate change, where there is a globally recognized need to reduce greenhouse gas emissions and enhance carbon sequestration in soil. Consequently, there has been an increasing demand for tools that can accurately measure and predict the impact of agronomic events on the environment, while still considering various factors such as resource use, waste production, and carbon emissions.

However, traditional agronomic impact estimation systems, which rely mainly on manual model creation and laborious data compilation, are inefficient and provide limited capabilities for large scale monitoring. Moreover, these processes rely heavily on expert knowledge in the agronomy sector, a resource that is often scarce and subject to rapid obsolescence due to changes in agricultural practices, supply chains, and technologies. Still further, traditional methods of making such estimations, such as naïve Monte Carlo simulations, are computationally expensive, especially when scaled up to cover a large number of fields and farming activities. The simulations also tend to overlook covariance between different agronomic activities, which can lead to errors in impact estimation.

In other words, traditional estimations methods (such as Monte Carlo simulations that do not account for variance across many simulations, or more traditional individual model generation and curation) leave much room for technological improvements. The systems and methods described herein solve and/or alleviate many of these issues.

### SUMMARY

In some aspects, the techniques described herein relate to a method for generating an aggregated impact value, including: ingesting, at a computing device, data representing one or more agronomic event; and applying, at the computing device an impact prediction model to the one or more agronomic event, the impact prediction model: decomposing, based on the data, the one or more agronomic events into a series of agronomic activities; encoding the series of agronomic activities into a reference data object including a series of reference activities corresponding to the series of activities; accessing a precomputed translation array corresponding to the reference data object, wherein: the precomputed translation array includes precalculated impact factors corresponding to each reference activity in the series of reference activities, and the precalculated impact factors are generated based on a plurality of error-aware Monte-Carlo simulations; determining, for each activity in the series of activities, an impact value using the encoded reference data object and the precomputed translation array; determining an impact value for the one or more agronomic event by aggregating the impact value for the series of activities; and outputting the aggregated impact value.

In some aspects, the techniques described herein relate to a method, wherein decomposing the one or more agronomic event into a series of agronomic activities includes: populating one or more missing activity for the one or more agronomic events.

In some aspects, the techniques described herein relate to a method, wherein decomposing the one or more agronomic event into a series of agronomic activities includes: mapping the one or more agronomic event to a reference activity in the series of reference activities.

In some aspects, the techniques described herein relate to a method, wherein the impact value is an emissions output.

In some aspects, the techniques described herein relate to a method, wherein the precomputed translation array is generated by running an impact model on a database accessed from a datastore.

In some aspects, the techniques described herein relate to a method, wherein the impact model is an emissions model.

In some aspects, the techniques described herein relate to a method, encoding the series of agronomic activities into a reference data object includes: generating elements in the reference data object representing the series of agronomic activities; and weighting the elements based on attributes associated with the agronomic event.

In some aspects, the techniques described herein relate to a method, wherein the weighted elements associated representing the series of agronomic activities includes non-linear activities and co-variance factors.

In some aspects, the techniques described herein relate to a method, wherein precomputed translation array includes uncertainty values, and wherein aggregating the impact value for each agronomic event includes aggregating the uncertainty values.

In some aspects, the techniques described herein relate to a method, further including: for each agronomic event of a plurality of agronomic events, generating one or more matrices configured to aggregate the impact of the agronomic event; and selecting one or more of the generated matrices for the agronomic event as the translation array.

In some aspects, the techniques described herein relate to a method, further including: reading a series of activity definitions and uncertainty distributions for the one or more agronomic event; generating a unique model ID to identify a set of randomly-sampled matrices; generating a set of randomly sampled matrices; and saving the set of randomly sampled matrices for reuse.

In some aspects, the techniques described herein relate to a method, wherein the impact value for each agronomic event includes a pre-field emissions score.

In some aspects, the techniques described herein relate to a method, wherein the impact value for each agronomic event includes on-field emissions scores.

In some aspects, the techniques described herein relate to a method, further including receiving emissions values for additional agronomic events from alternative emissions models.

In some aspects, the techniques described herein relate to a method, wherein the agronomic event includes at least one of fertilization, tillage, grazing, irrigation, planting, and/or harvesting.

In some aspects, the techniques described herein relate to a method, wherein the one or more agronomic event is measured over a partial crop rotation or a complete crop rotation.

In some aspects, the techniques described herein relate to a method, wherein each set of reference activities has an associated frequency.

In some aspects, the techniques described herein relate to a method, further including: generating the precomputed translation array by: reading in an activity information as a CSV; generating a unique model identification to identify a set of randomly-sampled matrices; saving the randomly-sampled matrices for reuse; and providing a randomly sampled matrix of the randomly sampled matrices as a precomputed reference matrix.

In some aspects, the techniques described herein relate to a method, wherein the data representing agronomic events include remote sensing data.

In some aspects, the techniques described herein relate to a method, further including monitoring remote sensing data corresponding to one or more geographic regions, detecting a presence, absence, or change in an agronomic event within the region based on the remote sensing data, and automatically applying the impact prediction model.

In some aspects, the techniques described herein relate to a system including: one or more processors; a non-transitory computer-readable storage medium including computer program instructions for generating an aggregated impact value, the computer program instructions, when executed by the one or more processors, causing the one or more processors to: applying, at the computing device an impact prediction model to the one or more agronomic event, the impact prediction model: decompose, based on the data, the one or more agronomic events into a series of agronomic activities; encode the series of agronomic activities into a reference data object including a series of reference activities corresponding to the series of activities; access a precomputed translation array corresponding to the reference data object, wherein: the precomputed translation array includes precalculated impact factors corresponding to each reference activity in the series of reference activities, and the precalculated impact factors are generated based on a plurality of error-aware Monte-Carlo simulations; determine, for each activity in the series of activities, an impact value using the encoded reference data object and the precomputed translation array; determine an impact value for the one or more agronomic event by aggregating the impact value for the series of activities; and output the aggregated impact value.

In some aspects, the techniques described herein relate to a non-transitory computer-readable storage medium including computer program instructions for generating an aggregated impact value, the computer program instructions, when executed by the one or more processors, causing the one or more processors to: applying, at the computing device an impact prediction model to the one or more agronomic event, the impact prediction model: decompose, based on the data, the one or more agronomic events into a series of agronomic activities; encode the series of agronomic activities into a reference data object including a series of reference activities corresponding to the series of activities; access a precomputed translation array corresponding to the reference data object, wherein: the precomputed translation array includes precalculated impact factors corresponding to each reference activity in the series of reference activities, and the precalculated impact factors are generated based on a plurality of error-aware Monte-Carlo simulations; determine, for each activity in the series of activities, an impact value using the encoded reference data object and the precomputed translation array; determine an impact value for the one or more agronomic event by aggregating the impact value for the series of activities; and output the aggregated impact value.

### BRIEF DESCRIPTION OF THE DRAWINGS

The accompanying drawings, which are incorporated into and constitute a part of this specification, illustrate various exemplary embodiments and together with the description, serve to explain the principles of the disclosed embodiments.

FIG. 1 (“FIG. 1”) is a flow diagram illustrating a method for collecting a greenhouse gas emissions inventory, according to embodiments of the present disclosure.

FIG. 2 is an illustration of an equation to find a point estimate, according to embodiments of the present disclosure.

FIG. 3 is an exemplary workflow for estimating a CO2e impact estimate, according to embodiments of the present disclosure.

FIG. 4 is an exemplary workflow for a Monte Carlo simulation, according to embodiments of the present disclosure.

FIG. 5 is an exemplary workflow for populating an A matrix, according to embodiments of the present disclosure.

FIG. 6 is an exemplary workflow for populating a B matrix, according to embodiments of the present disclosure.

FIG. 7 is an exemplary workflow for parsing a .spold file, according to embodiments of the present disclosure.

FIG. 8 is an exemplary workflow for scaling an A matrix, according to embodiments of the present disclosure.

FIG. 9 is an exemplary workflow for generating a point estimate for global warming impact, according to embodiments of the present disclosure.

FIG. 10 is an exemplary workflow for generating Monte Carlo estimates for a global warming impact, according to embodiments of the present disclosure.

FIGS. 11A and 11B are exemplary workflows for incorporating uncertainty, according to embodiments of the present disclosure.

FIG. 12 is a computing node, according to embodiments of the present disclosure.

FIG. 13 is a block diagram that illustrates an ecosystem management environment, according to embodiments of the present disclosure.

FIG. 14 is a block diagram illustrating an impact estimation module, according to embodiments of the present disclosure.

FIG. 15 illustrates a workflow diagram for generating an aggregated impact value for an agronomic event, according to embodiments of the present disclosure.

### DETAILED DESCRIPTION

For many types of mathematical models, including input-output models, it is necessary to solve systems of equations to obtain an answer. For example, life-cycle inventories typically represent the amount of material flowing between manufacturing, transportation, and other processes as an input-output model (i.e., an input-output matrix), and it is necessary to solve a system of equations to determine how much of each input is required for a particular activity or set of activities. Input-output models, originally developed as a tool for economic planning, are still most commonly used in economics. Solving this system of equations is typically part of the calculations in a life-cycle analysis, and enable a determination of environmental impacts such as greenhouse gas emissions. Life-cycle analysis (LCA) is a method of determining the environmental impact of a product through its entire lifecycle from the extraction of raw materials, manufacturing, distribution, use, and disposal.

Solving a system of equations typically requires many calculation steps, which can lead to long run-times. This is particularly relevant when many systems of equations must be solved. For example, in life-cycle inventories, to account for the uncertainty in how much material flows between processes, it is typical to conduct a Monte Carlo simulation in which many input-output matrices are generated, each representing a different system of equations that must be solved. Generating and solving large systems of equations in real-time, such as the matrices used in life-cycle inventories, can be prohibitively slow. High-performance linear algebra packages can reduce run-time, but may not be available to all software developers and may not be sufficient depending on the application, and even high-performance linear algebra packages are not alone sufficient to reduce run-times to required levels for some applications. A faster run time makes new applications more feasible. Pre-computing the solutions to these systems of equations is another strategy to decrease run-time, but naive pre-computation methods would not allow the results to be aggregated in a way that accurately quantifies variance. In embodiments of the present disclosure, a pre-computation method is described that preserves the ability to quantify variance, while reducing run-time and enabling subsequent analyses.

In embodiments of the present disclosure, the methods of the present invention are applied to greenhouse gas inventory models. When applied to greenhouse gas inventory models a database “rollup” includes a large set of precomputed emissions for each activity from randomly-sampled model matrices. Having these samples allows for the scaling and aggregation of emissions for combinations of activities in a way that accounts for co-variance between component activity emissions explicitly.

In one embodiment, a method comprises ingesting events (for example, agronomic events) and populating missing event details. The method includes translating each event into a set of database activities and their amounts then computing emissions (kg CO2-equivalent, “kg CO2e”) for each activity using impact factors (for example, TRACI impact factors, TRACI is an EPA method for equating emissions to various impact categories). The method also aggregates emissions for each high-level event to provide total value for emissions, for example emissions per operation or unit or area (for example, “kg CO2e per field”).

Reference will now be made in detail to the exemplary embodiments of the present disclosure, examples of which are illustrated in the accompanying drawings. Wherever possible, the same reference numbers will be used throughout the drawings to refer to the same or like parts.

The systems, devices, and methods disclosed herein are described in detail by way of examples and with reference to the figures. The examples discussed herein are examples only and are provided to assist in the explanation of the apparatuses, devices, systems, and methods described herein. None of the features or components shown in the drawings or discussed below should be taken as mandatory for any specific implementation of any of these devices, systems, or methods unless specifically designated as mandatory.

Also, for any methods described, regardless of whether the method is described in conjunction with a flow diagram, it should be understood that unless otherwise specified or required by context, any explicit or implicit ordering of steps performed in the execution of a method does not imply that those steps must be performed in the order presented but instead may be performed in a different order or in parallel.

As used herein, the term “exemplary” is used in the sense of “example,” rather than “ideal.” Moreover, the terms “a” and “an” herein do not denote a limitation of quantity, but rather denote the presence of one or more of the referenced items.

### Definitions

As used herein, “reference inventory database” or “reference database” refers to a database of reference activities (comprising inputs and outputs of that activity relative to the natural environment (known as elementary exchanges) and human-made or human-modified environment (i.e., other activities) (known as intermediate exchanges)). Reference databases, vary in how files and product boundaries are defined, for example, unit processes which represent individual processes or activities and their elementary and intermediate exchanges, and cumulative life cycle inventories which aggregate like elementary exchanges across all activities within with a supply chain. Reference databases may be comprised of any variety of different file types; a common example file type of life-cycle inventory databases is the spold file. Examples of spold files include individual unit processes (UPR) spold files and life-cycle inventory (LCI) spold files. The LCI files contain the “rolled-up” emissions for a single activity. The UPR files define the model coefficients that were used to generate the LCI emissions totals. LCI files do not contain uncertainty. Embodiments of the present disclosure describe methods of generating pre-computed rollups that can support uncertainty calculations for combinations of activities.

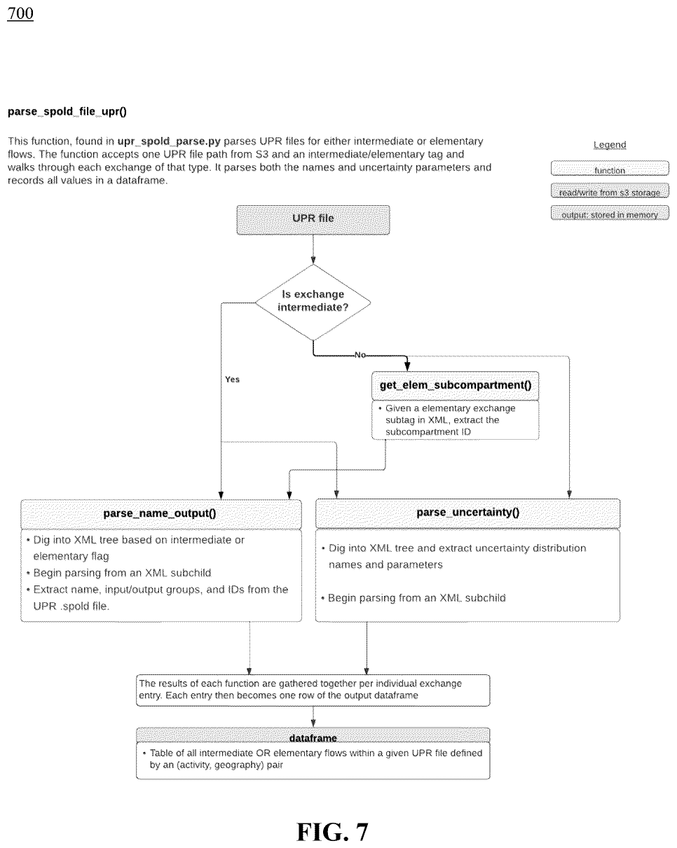

A UPR file is an entity that describes an action, like producing fertilizer (e.g., market for urea ammonium nitrate mi), and defines the exchanges between that activity and the environment (elementary exchange) as well as the interactions between that activity and other activities (intermediate exchange). Individual files (˜20k) contain both intermediate and elementary exchange information with associated uncertainty distributions. This information and file format can be used to calculate climate change impact estimates with uncertainty. To do so, the appropriate information is extracted from the twenty thousand files by parsing each file. This parsed information then populates an input-output model. An exemplary method 700 for parsing a .spold file is shown in FIG. 7.

As used herein, “reference activity” refers to a data relating to an activity or process (for example, an agronomic activity). In some embodiments, a reference activity includes emissions information pertaining to the activity or process (for example, including emissions released to soil, air, water, etc.). In some embodiments, a reference activity includes information on the inputs required by an activity or process as well as the products, co-products, and waste produced by an activity or process. In some embodiments, a reference activity includes information on the boundary for which each activity or process is modeled, i.e., where the emissions accounting starts and stops. A boundary may be specified on several dimensions including the boundary between the technical system and nature, delimitation of the geographic area and time horizon, boundaries of the life-cycle of the product of interest and related life-cycles of other products. Exemplary models described herein use reference databases, for example, a life cycle inventory database. Examples of lifecycle inventory databases include without limitation ecoinvent database, CEDA database, CCaLC database, E3IOT database, ELCD database, LCA Commons, IDEA, Agri-footprint, Agribalyse, ESU World Food, etc.

As used herein, “agronomic event” (equivalently “crop production practices”, or “farming practice”) are actions taken or avoided in the process of producing an agricultural crop. A farming practice is often associated with one or more of a location (for example, a point location or an area, for example, one or more field, an area within a field boundary (or production facility), etc.) and a specified time (e.g., at a particular time and or date, for example a planting date) or time period (e.g., crop season or year). Such actions taken or avoided may include, without limitation, planting a crop, planting a particular variety of seed (e.g., a non-GMO seed), planting a cover-crop, one or more cover crop species planted, using a particular tillage technique (including not tilling), irrigation type, using water conservation techniques, using or not using pesticides or insecticides, an input applied (for example, a fertilizer, manure, one or more microbe, a material for direct air capture of a greenhouse gas, a silicate material (for example, crushed silicate rock such as basalt), a material for passive direct air capture of a greenhouse gas), a harvesting technique, a type and or amount of field residue, a field residue burning event, etc., In various embodiments, farming practices may apply to entire fields, to more than one field, or subregions or points within a field. Within a single crop season some farming practices may be applied to an entire field, while other farming practices may be applied to a subfield region.

As used herein, “reference geography” refers to a predefined geography tag for each reference activity. The geography tags correspond to specific regions around the world, anything from individual states to entire continents. In general, the model matches field locations with “market for” activities which just means the emissions for those activities are associated with typical purchasing markets for the assigned geography. Example: “market for urea-US” represents emissions associated with a typical unit of urea purchased and used in the US, including emissions from weighted modes of transportation represented in the market.

The teachings of the present disclosure are suitable for use with a variety of databases or models providing a system mapping agricultural activities to ecological impacts such as emissions.

As used herein an “ecosystem benefit” is used equivalently with “ecosystem attribute” or “environmental attribute,” each refer to an environmental characteristic (for example, as a result of agricultural production) that may be quantified and valued (for example, as an ecosystem credit or sustainability claim). Examples of ecosystem benefits include without limitation reduced water use, reduced nitrogen use, increased soil carbon sequestration, greenhouse gas emission avoidance, etc. An example of a mandatory program requiring accounting of ecosystem attributes is California's Low Carbon Fuel Standard (LCFS). Field-based agricultural management practices can be a means for reducing the carbon intensity of biofuels (e.g., biodiesel from soybeans). As used herein, reference to an emissions or emissions outputs refer to amount of emission of one or more compositions, for example, one or more greenhouse gas. Methods described herein in reference to emissions are equally applicable to any other quantifiable ecosystem attribute.

More generally, a counterfactual scenario refers to what could have happened within the crop growing season in an area of land given alternative practices. In various embodiments, a counterfactual scenario is based on an approximation of supply shed practices.

An “ecosystem credit” is a unit of value corresponding to an ecosystem benefit or ecosystem impact, where the ecosystem attribute or ecosystem impact is measured, verified, and or registered according to a methodology. In some embodiments, an ecosystem credit may be a report of the inventory of ecosystem attributes (for example, an inventory of ecosystem attributes of a management zone, an inventory of ecosystem attributes of a farming operation, an inventory of ecosystem attributes of a supply shed, an inventory of ecosystem attributes of a supply chain, an inventory of a processed agricultural product, etc.). In some embodiments, an ecosystem credit is a life-cycle assessment. In some embodiments, an ecosystem credit may be a registry issued credit. Optionally, an ecosystem credit is generated according to a methodology approved by an issuer. An ecosystem credit may represent a reduction or offset of an ecologically significant compound (e.g., carbon credits, water credits, nitrogen credits). In some embodiments, a reduction or offset is compared to a baseline of ‘business as usual’ if the ecosystem crediting or sustainability program did not exist (e.g., if one or more practice change made because of the program had not been made).

In some embodiments, a reduction or offset is compared to a baseline of one or more ecosystem attributes (e.g., ecosystem attributes of one or more: field, sub-field region, county, state, region of similar environment, supply shed geographic region, a supply shed, etc.) during one or more prior production period. For example, ecosystem attributes of a field in 2022 may be compared to a baseline of ecosystem attributes of the field in 2021. In some embodiments, a reduction or offset is compared to a baseline of one or more ecosystem attributes (e.g., ecosystem attributes of one or more: field, sub-field region, county, state, region of similar environment, supply shed geographic region, a supply shed, etc.) during the same production period. For example, ecosystem attributes of a field may be compared to a baseline of ecosystem attributes of a supply shed comprising the field. An ecosystem credit may represent a permit to reverse an ecosystem benefit, for example, a license to emit one metric ton of carbon dioxide. A carbon credit represents a measure (e.g., one metric ton) of carbon dioxide or other greenhouse gas emissions reduced, avoided or removed from the atmosphere. A nutrient credit, for example a water quality credit, represents pounds of a chemical removed from an environment (e.g., by installing or restoring nutrient-removal wetlands) or reduced emissions (e.g., by reducing rates of application of chemical fertilizers, managing the timing or method of chemical fertilizer application, changing type of fertilizer, etc.). Examples of nutrient credits include nitrogen credits and phosphorous credits. A water credit represents a volume (e.g., 1000 gallons) of water usage that is reduced or avoided, for example by reducing irrigation rates, managing the timing or method of irrigation, employing water conservation measures such as reducing evaporation application.

A “sustainability claim” is a set of one or more ecosystem benefits associated with an agricultural product (for example, including ecosystem benefits associated with production of an agricultural product). Sustainability claims may or may not be associated with ecosystem credits. For example, a consumer package good entity may contract raw agricultural products from producers reducing irrigation, in order to make a sustainability claim of supporting the reduction of water demand on the final processed agricultural product. The producers reducing irrigation may or may not also participate in a water ecosystem credit program, where ecosystem credits are generated based on the quantity of water that is actually reduced compared against a baseline.

“Offsets” are credits generated by third-parties outside the value chain of the party with the underlying carbon liability (e.g., oil company that generates greenhouse gases from combusting hydrocarbons purchases carbon credit from a farmer).

“Insets” are ecosystem resource (e.g., carbon dioxide) reductions within the value chain of the party with the underlying carbon liability (e.g., oil company who makes biodiesel reduces carbon intensity of biodiesel by encouraging farmers to produce the underlying soybean feedstock using sustainable farming practices). Insets are considered Scope 1 reductions.

Emissions of greenhouse gases are often categorized as Scope 1, Scope 2, or Scope 3. Scope 1 emissions are direct greenhouse gas emissions that occur from sources that are controlled or owned by an organization. Scope 2 emissions are indirect greenhouse gas emissions associated with purchase of electricity, stem, heating, or cooling. Scope 3 emissions are the result of activities from assets not owned or controlled by the reporting organization, but that the organization indirectly impacts in its value chain. Scope 3 emissions represent all emissions associated with an organization's value chain that are not included in that organization's Scope 1 or Scope 2 emissions. Scope 3 emissions include activities upstream of the reporting organization or downstream of the reporting organization. Upstream activities include, for example, purchased goods and services (e.g., agricultural production such as wheat, soybeans, or corn may be purchased inputs for production of animal feed), upstream capital goods, upstream fuel and energy, upstream transportation and distribution (e.g., transportation of raw agricultural products such as grain from the field to a grain elevator), waste generated in upstream operations, business travel, employee commuting, or leased assets. Downstream activities include, for example, transportation and distribution other than with the vehicles of the reporting organization, processing of sold goods, use of goods sold, end of life treatment of goods sold, leased assets, franchises, or investments.

An ecosystem credit may generally be categorized as either an inset (when associated with the value chain of production of a particular agricultural product), or an offset, but not both concurrently.

As used herein, a “crop-growing season” may refer to fundamental unit of grouping crop events by non-overlapping periods of time. In various embodiments, harvest events are used where possible.

An “issuer” is an issuer of ecosystem credits, which may be a regulatory authority or another trusted provider of ecosystem credits. An issuer may alternatively be referred to as a “registry”.

A “token” (alternatively, an “ecosystem credit token”) is a digital representation of an ecosystem benefit, ecosystem impact, or ecosystem credit. The token may include a unique identifier representing one or more ecosystem credits, ecosystem attribute, or ecosystem impact, or, in some embodiments a putative ecosystem credit, putative ecosystem attribute, or putative ecosystem impact, associated with a particular product, production location (e.g., a field), production period (e.g., crop production season), and/or production zone cycle (e.g., a single management zone defined by events that occur over the duration of a single crop production season).

“Ecosystem credit metadata” is at least information sufficient to identify an ecosystem credit issued by an issuer of ecosystem credits. For example, the metadata may include one or more of a unique identifier of the credit, an issuer identifier, a date of issuance, identification of the algorithm used to issue the credit, or information regarding the processes or products giving rise to the credit. In some embodiments, the credit metadata may include a product identifier as defined herein. In other embodiments, the credit is not tied to a product at generation, and so there is no product identifier included in the credit metadata.

A “product” is any item of agricultural production, including crops and other agricultural products, in their raw, as-produced state (e.g., wheat grains), or as processed (e.g., oils, flours, polymers, consumer goods (e.g., crackers, cakes, plant based meats, animal-based meats (for example, beef from cattle fed a product such as corn grown from a particular field), bioplastic containers, etc.). In addition to harvested physical products, a product may also include a benefit or service provided via use of the associated land (for example, for recreational purposes such as a golf course), pasture land for grazing wild or domesticated animals (where domesticated animals may be raised for food or recreation).

“Product metadata” are any information regarding an underlying product, its production, and/or its transaction which may be verified by a third party and may form the basis for issuance of an ecosystem credit and/or sustainability claim. Product metadata may include at least a product identifier, as well as a record of entities involved in transactions.

As used herein, “quality” or a “quality metric” may refer to any aspect of an agricultural product that adds value. In some embodiments, quality is a physical or chemical attribute of the crop product. For example, a quality may include, for a crop product type, one or more of: a variety; a genetic trait or lack thereof; genetic modification of lack thereof; genomic edit or lack thereof; epigenetic signature or lack thereof; moisture content; protein content; carbohydrate content; ash content; fiber content; fiber quality; fat content; oil content; color; whiteness; weight; transparency; hardness; percent chalky grains; proportion of corneous endosperm; presence of foreign matter; number or percentage of broken kernels; number or percentage of kernels with stress cracks; falling number; farinograph; adsorption of water; milling degree; immature grains; kernel size distribution; average grain length; average grain breadth; kernel volume; density; L/B ratio; wet gluten; sodium dodecyl sulfate sedimentation; toxin levels (for example, mycotoxin levels, including vomitoxin, fumonisin, ochratoxin, or aflatoxin levels); and damage levels (for example, mold, insect, heat, cold, frost, or other material damage).

In some embodiments, quality is an attribute of a production method or environment. For example, quality may include, for a crop product, one or more of: soil type; soil chemistry; climate; weather; magnitude or frequency of weather events; soil or air temperature; soil or air moisture; degree days; rain fed; irrigated or not; type of irrigation; tillage frequency; cover crop (present or historical); fallow seasons (present or historical); crop rotation; organic; shade grown; greenhouse; level and types of fertilizer use; levels and type of chemical use; levels and types of herbicide use; pesticide-free; levels and types of pesticide use; no-till; use of organic manure and byproducts; minority produced; fair-wage; geography of production (e.g., country of origin, American Viticultural Area, mountain grown); pollution-free production; reduced pollution production; levels and types of greenhouse gas production; carbon neutral production; levels and duration of soil carbon sequestration; and others. In some embodiments, quality is affected by, or may be inferred from, the timing of one or more production practices. For example, food grade quality for crop products may be inferred from the variety of plant, damage levels, and one or more production practices used to grow the crop. In another example, one or more qualities may be inferred from the maturity or growth stage of an agricultural product such as a plant or animal. In some embodiments, a crop product is an agricultural product.

In some embodiments, quality is an attribute of a method of storing an agricultural good (e.g., the type of storage: bin, bag, pile, in-field, box, tank, or other containerization), the environmental conditions (e.g., temperature, light, moisture, relative humidity, presence of pests, CO2 levels) during storage of the crop product, method of preserving the crop product (e.g., freezing, drying, chemically treating), or a function of the length of time of storage. In some embodiments, quality may be calculated, derived, inferred, or subjectively classified based on one or more measured or observed physical or chemical attributes of a crop product, its production, or its storage method. In some embodiments, a quality metric is a grading or certification by an organization or agency. For example, grading by the USDA, organic certification, or non-GMO certification may be associated with a crop product. In some embodiments, a quality metric is inferred from one or more measurements made of plants during growing season. For example, wheat grain protein content may be inferred from measurement of crop canopies using hyperspectral sensors and/or NIR or visible spectroscopy of whole wheat grains. In some embodiments, one or more quality metrics are collected, measured, or observed during harvest. For example, dry matter content of corn may be measured using near-infrared spectroscopy on a combine. In some embodiments, the observed or measured value of a quality metric is compared to a reference value for the metric. In some embodiments, a reference value for a metric (for example, a quality metric or a quantity metric) is an industry standard or grade value for a quality metric of a particular agricultural good (for example, U.S. No. 3 Yellow Corn, Flint), optionally as measured in a particular tissue (for example, grain) and optionally at a particular stage of development (for example, silking). In some embodiments, a reference value is determined based on a supplier's historical production record or the historical production record of present and/or prior marketplace participants.

A “field” is the area where agricultural production practices are being used (for example, to produce a transacted agricultural product) and/or ecosystem credits and/or sustainability claims.

As used herein, a “field boundary” may refer to a geospatial boundary of an individual field.

As used herein, an “enrolled field boundary” may refer to the geospatial boundary of an individual field enrolled in at least one ecosystem credit or sustainability claim program on a specific date.

As used herein, a “management event” may refer to a grouping of data about one or more farming practices (such as tillage, harvest, etc.) that occur within a field boundary or an enrolled field boundary. A “management event” contains information about the time when the event occurred, and has a geospatial boundary defining where within the field boundary the agronomic data about the event applies. Management events are used for modeling and credit quantification, designed to facilitate grower data entry and assessment of data requirements. Each management event may have a defined management event boundary that can be all or part of the field area defined by the field boundary. A “management event boundary” (equivalently a “farming practice boundary”) is the geospatial boundary of an area over which farming practice action is taken or avoided. In some embodiments, if a farming practice action is an action taken or avoided at a single point, the management event boundary is point location. As used herein, a farming practice and agronomic practice are of equivalent meaning.

As used herein, a “management zone” may refer to an area within an individual field boundary defined by the combination of management event boundaries that describe the presence or absence of management events at any particular time or time window, as well as attributes of the management events (if any event occurred). A management zone may be a contiguous region or a non-contiguous region. A “management zone boundary” may refer to a geospatial boundary of a management zone. In some embodiments, a management zone is an area coextensive with a spatially and temporally unique set of one or more farming practices. In some embodiments, an initial management zone includes historic management events from one or more prior cultivation cycles (for example, at least 2, at least 3, at least 4, at least 5, or a number of prior cultivation cycles required by a methodology). In some embodiments, a management zone generated for the year following the year for which an initial management zone was created will be a combination of the initial management zone and one or more management event boundaries of the next year. A management zone can be a data-rich geospatial object created for each field using an algorithm that crawls through management events (e.g., all management events) and groups the management events into discrete zonal areas based on features associated with the management event(s) and/or features associated with the portion of the field in which the management event(s) occur. The creation of management zones enables the prorating of credit quantification for the area within the field boundary based on the geospatial boundaries of management events.

In some embodiments, a management zone is created by sequentially intersecting a geospatial boundary defining a region wherein management zones are being determined (for example, a field boundary), with each geospatially management event boundary occurring within that region at any particular time or time window, wherein each of the sequential intersection operations creates two branches-one with the intersection of the geometries and one with the difference. The new branches are then processed with the next management event boundary in the sequence, bifurcating whenever there is an area of intersection and an area of difference. This process is repeated for all management event boundaries that occurred in the geospatial boundary defining the region. The final set of leaf nodes in this branching process define the geospatial extent of the set of management zones within the region, wherein each management zone is non-overlapping and each individual management zone contains a unique set of management events relative to any other management zone defined by this process.

As used herein, a “zone-cycle” may refer to a single cultivation cycle on a single management zone within a single field, considered collectively as a pair that define a foundational unit (e.g., also referred to as an “atomic unit”) of quantification for a given field in a given reporting period.

As used herein, a “baseline simulation” may refer to a point-level simulation of constructed baselines for the duration of the reported project period, using initial soil sampling at that point (following SEP requirements for soil sampling and model initialization) and management zone-level grower data (that meets SEP data requirements).

As used herein, a “with-project simulation” may refer to a point-level simulation of adopted practice changes at the management zone level that meet SEP requirements for credit quantification.

As used herein, a “field-level project start date” may refer to the start of the earliest cultivation cycle, where a practice change was detected and attested by a grower.

As used herein, a “required historic baseline period” may refer to years (in 365 day periods, not calendar years) of required historic information prior to the field-level project start date that must fit requirements of the data hierarchy in order to be modeled for credits. A number of required years is specified by the SEP, based on crop rotation and management.

As used herein, a “cultivation cycle” (equivalently a “crop production period” or “production period”) may refer to the period between the first day after harvest or cutting of a prior crop on a field or the first day after the last grazing on a field, and the last day of harvest or cutting of the subsequent crop on a field or the last day of last grazing on a field. For example, a cultivation cycle may be: a period starting with the planting date of current crop and ending with the harvest of the current crop, a period starting with the date of last field prep event in the previous year and ending with the harvest of the current crop, a period starting with the last day of crop growth in the previous year and ending with the harvest or mowing of the current crop, a period starting the first day after the harvest in the prior year and the last day of harvest of the current crop, etc. In some embodiments, cultivation cycles are approximately 365 day periods from the field-level project start date that contain completed crop growing seasons (planting to harvest/mowing, or growth start to growth stop). In some embodiments, cultivation cycles extend beyond a single 365 day period and cultivation cycles are divided into one or more cultivation cycles of approximately 365 days, optionally where each division of time includes one planting event and one harvest or mowing event.

As used herein, a “historic cultivation cycles” may refer to defined in the same way as cultivation cycles, but for the period of time in the required historic baseline period.

As used herein, a “historic segments” may refer to individual historic cultivation cycles, separated from each other in order to use to construct baseline simulations.

As used herein, a “historic crop practices” may refer to crop events occurring within historic cultivation cycles.

As used herein, a “baseline thread/parallel baseline threads” may refer to each baseline thread is a repeating cycle of the required historic baseline period, that begin at the management zone level project start date. The number of baseline threads equals the number of unique historic segments (e.g., one baseline thread per each year of the required historic baseline period). Each baseline thread begins with a unique historic segment and runs in parallel to all other baseline threads to generate baseline simulations for a with-project cultivation cycle.

As used herein, an “overlap in practices” may refer to an unrealistic agronomic combinations that arise at the start of baseline threads, when dates of agronomic events in the concluding cultivation cycle overlap with dates of agronomic events in the historic segment that is starting the baseline thread. In this case, logic is in place based on planting dates and harvest dates to make adjustments based on the type of overlap that is occurring.

An “indication of a geographic region” is a latitude and longitude, an address or parcel id, a geopolitical region (for example, a city, county, state), a region of similar environment (e.g., a similar soil type or similar weather), a supply shed, a boundary file, a shape drawn on a map presented within a GUI of a user device, image of a region, an image of a region displayed on a map presented within a GUI of a user device, a user id where the user id is associated with one or more production locations (for example, one or more fields).

For example, polygons representing fields may be detected from remote sensing data using computer vision methods (for example, edge detection, image segmentation, and combinations thereof) or machine learning algorithms (for example, maximum likelihood classification, random tree classification, support vector machine classification, ensemble learning algorithms, convolutional neural network, etc.).

“Ecosystem observation data” are observed or measured data describing an ecosystem, for example weather data, soil data, remote sensing data, emissions data (for example, emissions data measured by an eddy covariance flux tower), populations of organisms, plant tissue data, and genetic data. In some embodiments, ecosystem observation data are used to connect agricultural activities with ecosystem variables. Ecosystem observation data may include survey data, such as soil survey data (e.g., SSURGO). In various embodiments, the system performs scenario exploration and model forecasting, using the modeling described herein. In various embodiments, the system proposes climate-smart crop fuel feedstock CI integration with an existing model, such as the Greenhouse gases, Regulated Emissions, and Energy use in Technologies Model (GREET), which can be found online at https://greet.es.anl.gov/(the GREET models are incorporated by reference herein).

A “crop type data layer” is a data layer containing a prediction of crop type, for example USDA Cropland Data Layer provides annual predictions of crop type, and a 30 m resolution land cover map is available from MapBiomas (https://mapbiomas.org/en). A crop mask may also be built from satellite-based crop type determination methods, ground observations including survey data or data collected by farm equipment, or combinations of two or more of: an agency or commercially reported crop data layer (e.g., CDL), ground observations, and satellite-based crop type determination methods.

A “vegetative index” (“VI”) is a value related to vegetation as computed from one or more spectral bands or channels of remote sensing data. Examples include simple ratio vegetation index (“RVI”), perpendicular vegetation index (“PVI”), soil adjusted vegetation index (“SAVI”), atmospherically resistant vegetation index (“ARVI”), soil adjusted atmospherically resistant VI (“SARVI”), difference vegetation index (“DVI”), normalized difference vegetation index (“NDVI”). NDVI is a measure of vegetation greenness which is particularly sensitive to minor increases in surface cover associated with cover crops.

“SEP” stands for soil enrichment protocol. The SEP version 1.0 and supporting documents, including requirements and guidance, (incorporated by reference herein) can be found online at https://www.climateactionreserve.org/how/protocols/soil-enrichment/. As is known in the art, SEP is an example of a carbon registry methodology, but it will be appreciated that other registries having other registry methodologies (e.g., carbon, water usage, etc.) may be used, such as the Verified Carbon Standard VM0042 Methodology for Improved Agricultural Land Management, v1.0 (incorporated by reference herein), which can be found online at https://verra.org/methodology/vm0042-methodology-for-improved-agricultural-land-management-v1-0/. The Verified Carbon Standard methodology quantifies the greenhouse gas (GHG) emission reductions and soil organic carbon (SOC) removals resulting from the adoption of improved agricultural land management (ALM) practices. Such practices include, but are not limited to, reductions in fertilizer application and tillage, and improvements in water management, residue management, cash crop and cover crop planting and harvest, and grazing practices.

“LRR” refers to a Land Resource Region, which is a geographical area made up of an aggregation of Major Land Resource Areas (MLRA) with similar characteristics.

Daycent is a daily time series biogeochemical model that simulates fluxes of carbon and nitrogen between the atmosphere, vegetation, and soil. It is a daily version of the CENTURY biogeochemical model. Model inputs include daily maximum/minimum air temperature and precipitation, surface soil texture class, and land cover/use data. Model outputs include daily fluxes of various N-gas species (e.g., N2O, NOx, N2); daily CO2 flux from heterotrophic soil respiration; soil organic C and N; net primary productivity; daily water and nitrate (NO3) leaching, and other ecosystem parameters.
“LCIA” refers to Life Cycle Impact Assessment.
“LCI” refers to Life Cycle Inventories.
“LCA” refers to Life Cycle Assessment.
“CF” refers to Characterization Factors.
“ASD” refers to Agricultural Statistical Districts.

Embodiments of the present disclosure describe inventory-based greenhouse gas emissions calculators. Embodiments can compute pre-field and on-field greenhouse gas emissions for a set of agronomic events (e.g., planting, harvest, tillage, etc.). In some embodiments, agronomic events may be determined by analysis of remote sensing data (e.g. satellite imagery). This is done to map an agricultural event stored from a field level to particular products in an ecosystem impact database or model (such as ecoinvent). Accordingly, various embodiments of the disclosure include translation steps and connection to a database used to look up ecosystem impacts such as emissions outputs.

Current and/or traditional systems to compute or simulate an overall impact of an agronomic event (e.g., carbon emissions) in a large number of fields are insufficient for several reasons. First, generating the model representing the agronomic event is a laborious process, and second, using traditional processes to scale the model to many fields is untenable.

To illustrate, consider the traditional development of a model to simulate the overall impact of an agronomic event. Current systems require manual curation of large databases to determine the series of activities that constitute that agronomic event. This entails manually compiling both the elementary and intermediate exchanges within an economic ecosystem that form the series of activities of the agronomic event. For example, consider a person trying to determine the impact of creating a bushel of corn. A person would determine various elementary exchanges that yield the corn directly—e.g., plowing the field, planting the seeds, spraying the seeds with water and herbicide, harvesting the corn, etc. The person would also determine various intermediate exchanges that yield the corn indirectly—e.g., producing the equipment to farm the rice, producing the fuel for that equipment, etc. This process is immensely time consuming and requires an in-depth knowledge of many sectors the agronomy economy and how they are interconnected. This knowledge is oftentimes not widely known, and where there is knowledge, it is quickly made outdated by changes in, e.g., farming processes, supply chains, technology, etc.

Once the set of activities leading to the agronomic activity are identified, the person can conceivably build a model to estimate the impact. To do so, they may assign various weights and probabilities to each of the connections between elementary and/or intermediate exchanges, those weights and probabilities quantifying a likelihood and a degree to which the corresponding activity contributes to the impact. Oftentimes, these weights and probabilities are particular to a particular field or region.

After all this work, the person can then simulate the environmental impact for a particular field in the future. The model is typically one that can account for some randomness and uncertainty for the field such as, e.g., a Monte Carlo simulation. Monte Carlo simulations are a mathematical method that predict the outcome of uncertain events by analyzing past data and predicting a range of future outcomes based on different choices of action. Thus, the Monte Carlo simulations are used to estimate an environmental impact associated with different products, processes, or activities across its entire life cycles. These traditional simulations solve a large system of linear equations each time the model is run and for each activity in question. Additionally, each model is usually run several times with different conditions to provide a range of impacts that could occur within the field. As an output, the model provides a distribution of predicted environmental impacts for a field based on the array of simulations.

This traditional process, overall, is inefficient, computationally expensive, and error prone.

To expand, the process is inefficient because the person must generate a model for each and every farming activity that is of interest. Most people do not have the specialized knowledge for this task, and both locating the correct tasks and generating the appropriate models is challenging for a single agronomic activity, much less multiple agronomic activities.

The process is computationally expensive because each time a person wants to generate a distribution of impacts (necessary for calculating an estimate or best-estimate and variance), they need run a large number of simulations to provide a well-founded result. While this process may be tenable for a single field and a single activity (e.g., a few minutes of processing time), expanding to multiple fields and multiple activities quickly becomes infeasible to perform in a reasonable amount of time (e.g., dozens of hours of processing time).

Finally, the process may be incomplete if impact estimates do not account for variance in the simulations (thereby leading to less accurate or incorrect estimations). To illustrate, consider simulating a first agronomic event. In this example, with each simulation, the amount of materials and energy required to produce everything consumed by the agronomic event, e.g. tractors, diesel, etc., are varied. For example, in one simulation the steel used to manufacture equipment, such as parts of the tractor, is assumed to require a first amount of kilowatt-hours per gram (kWh/g) of steel produced, whereas in another simulation steel production is assumed to require a different amount of kWh/g of steel produced. This process is repeated for every part that is used to produce all the machinery, chemical inputs, etc. Reference databases and scientific literature define reasonable distributions for these material flows.

Now, consider a Monte Carlo simulation that uses randomized draws when simulating many agricultural events, and which does not incorporate known dependencies between those events. In this case, when running hundreds of simulations, variations in the random assumption of the amount of materials and energy required to produce everything consumed by the agronomic events are not maintained within each simulation. For example, in the case of the tractor described above the assumption of the amount of energy and materials required to produce steel for a tractor used by one farmer may be different than the assumption of the amount of energy and materials required to produce steel for another farmer's tractor, even if the tractors were produced by the same manufacturer in the same factory and on the same day (e.g., the estimations should be the same). This may cause the impact of the farming machine to have an incorrect variance (e.g., variances that are too small). Accordingly, whatever simulated impact evaluation is determined using Monte Carlo methods that ignore known dependencies is error prone because it does not account for covariance correctly. That is, methods that do not account for correlations in the Monte Carlo simulations may introduce error in the variance and uncertainty of the estimated impact.

In order for traditional methods to account for covariance, they must run the Monte-Carlo analysis for each exact combination of activities. This is a significant limitation as aggregated impacts can only be generated for the pre-determined combinations of events that are modeled, and it is not possible to generate impacts broken down by event or activities within each event. Additionally, traditional methods are much less efficient when modelling a large number of fields, because the activity level results cannot be reused.

To solve these problems, the system described herein pre-computes and solves the systems of equations once upfront for each activity, rather than solving them repeatedly for each simulation run. The pre-computation also accounts for correlations in the simulations and enables calculations on thousands of fields quickly without a high computational burden. Methods of accounting for the covariance are described in greater detail below. Moreover, the system disclosed herein allows for farmers (or some other party) to efficiently compute emissions and its environmental impacts across different agronomic events without the need of developing ad hoc agronomic models on their own.

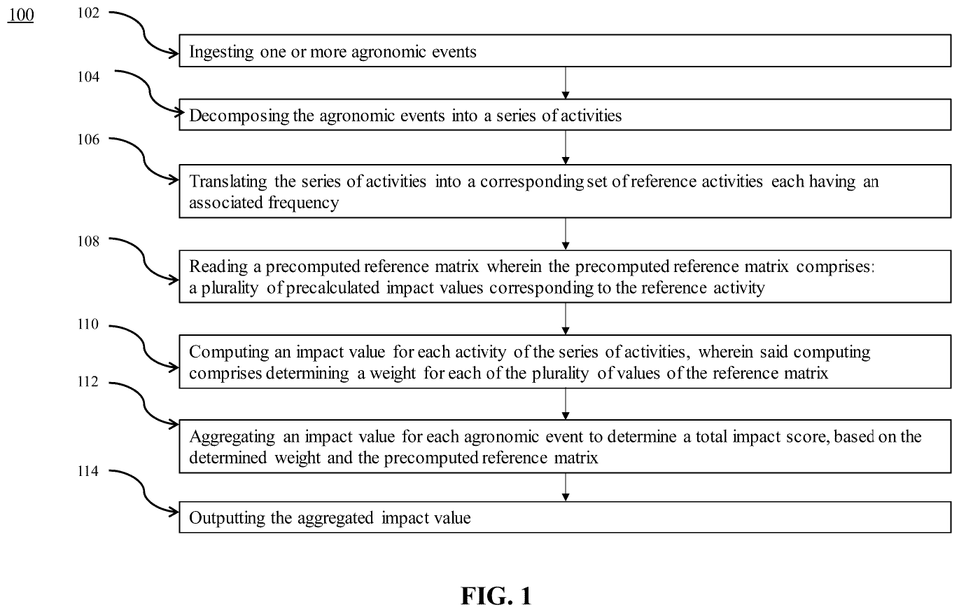

At a high level, embodiments of the model are reflected in the flowchart 100 in FIG. 1, includes ingesting 102 one or more agronomic event, decomposing 104 the one or more agronomic events into a series of activities, translating 106 the series of activities into a corresponding set of reference activities each having an associated amount, reading 108 a precomputed reference matrix wherein the precomputed reference matrix comprises a plurality of material flows corresponding to the reference activity, computing 110 a distribution of impact value for each activity of the series of activities. In FIG. 1, computing an impact value is done by 110 weighting the material flows by their impact factors. The model sums 112 the impact values for each agronomic event to determine a total impact value, based on the determined weight and the precomputed reference matrix and outputs 114 the aggregated impact value.

The method as described provides for a Monte Carlo simulation, a mathematical technique that predicts outcomes of an uncertain event. Computer programs use this method to analyze past data and predict a range of future outcomes based on a choice of action. Embodiments of the present disclosure function to run a Monte Carlo simulation more quickly than previously known. In a standard approach, a large sample of a large system of linear equations is solved each time a user wants to compute emissions for a set of activities. Assuming “solve” takes time X, each n time the model is run it will take nX. In the described approach, the application still solves similar systems of equations. Solving is done once, up front, for each activity. Assuming the number of activities is a, then the cost is aX. Comparing a and n shows a difference in runtimes. If n>a, the method will save overall compute time. If n<a, where there are only a few cases to solve, precomputation does not decrease the runtime.

To illustrate this scaling problem, consider an example where computing emissions for a single activity takes 1-3 seconds using the input-output model matrices (mainly to solve a ˜20k×˜20k sparse matrix equation). A reasonable sample size of ˜500 random samples will take on the order of 10 minutes for the single activity. Some events, such as agronomic events, include multiple activities. So, when using multiple farming events on multiple individual fields, the Monte Carlo simulations can take dozens of hours to complete. The techniques described herein reduce the Monte Carlo simulations to a single point estimate (e.g., from ecoinvent or another suitable simulation). The ability to rapidly compute impacts including correct uncertainties unlocks new applications, for example analyzing the impact of farmer management practices across large populations of fields across the country or world, or interactive exploration of the impact of different farm management practices on a specific field for the purposes of agronomic planning. Using alternatives such as OpenLCA, the same process would take significantly longer to complete. In particular, OpenLCA requires complete use of ecoinvent or other files, showing the impact for each product, and sorts through the existing emissions for known activities.

For example, embodiments of the present disclosure use LCI .spold files over UPR .spold files because of the smaller size and lesser downstream computation requirement, which leads to faster analysis. However, LCI .spold files do not contain uncertainty while UPR files do. UPR files contain a complete list of unit processes (electricity, natural gas, specific chemicals, etc.) needed to make one functional unit of a particular product or activity. The list of unit processes in each .spold file can be a mix of intermediate and elementary exchanges. Each intermediate exchange links to another UPR .spold file while each elementary exchange can be linked with TRACI impact factors. The links from intermediate exchanges to elementary exchanges to TRACI impact factors allows the calculation of the total TRACI impact of any intermediate exchange.

In the UPR files, the elementary exchanges (denoted by “elementaryExchangeIDs”) pertain only to material flows for the unit process in question. While UPR files contain intermediate and elementary exchanges, LCI files only contain elementary exchanges. In essence, LCI and UPR files contain the same information, but LCI files replace the intermediate exchanges that are found in the UPR files with elementary exchanges. This “replacement” from intermediate to elementary exchange involves an input/output model, as described below.

The speed of the Monte Carlo simulation as described herein is based on the use of precomputation. Emission outputs for known activities and events are calculated using the Tool for Reduction and Assessment of Chemicals Impacts (TRACI) and Other Environmental impacts factors, as illustrated in FIG. 1 and described below. In some embodiments, the system disclosed herein may determine whether to execute a Monte Carlo simulation or directly solve the input output model.

The method as shown in FIG. 1 can be used with any input/output model, including input/output models generated by Monte Carlo simulations, as the precomputation step is not model-specific. Inputs to the model can require a modified graph computed with different versions of the graph (this is completed at the pre-computation step).

An input/output model is typically used as a quantitative economic model that represents the interdependencies between different sectors of a national economy or different regional economies. Here, interdependencies between intermediate exchanges are used to calculate the equivalent CO2 emissions when one unit of a product is produced. The input-output model structures the relationships between intermediate exchanges, elementary exchanges, and TRACI impact factors as a matrix multiplication problem. This means that all of the data housed in UPR files must be parsed and restructured to fit the requirements of this model. Within the model, there are two primary matrices. The A_matrix describes intermediate←→intermediate exchange interactions, and the B_matrix describes intermediate←→elementary exchange interactions.

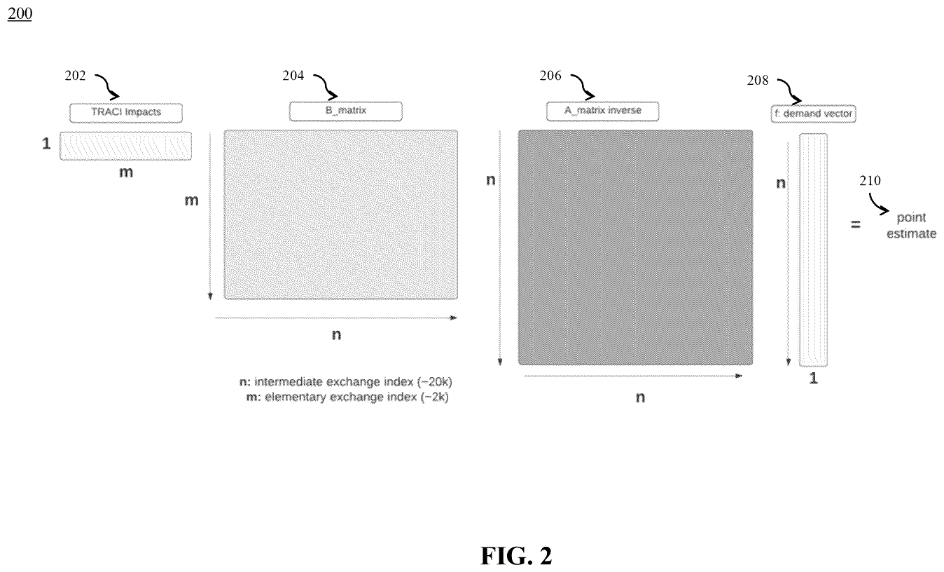

FIG. 2 illustrates an exemplary method 200 of calculating a point estimate 210 of CO₂ equivalent emissions. Two main matrices are labelled A_matrix and B_matrix. The A_matrix is size n×n that is composed of all n intermediate exchanges. Each column represents a single .spold file that describes the interactions between flows. Here, the negatives of the numeric values indicate what is required to produce one unit of the intermediate exchange of interest. For a given column/intermediate exchange, all rows in that column denote interactions with other intermediate exchanges. The B_matrix 204 is a size m×n matrix that is composed of m elementary exchanges and n intermediate exchanges. Here, each column of the matrix indicates an intermediate exchange, and all of the rows of that column denote the amount of elementary exchange material used by or emitted by that intermediate exchange.

Given a demand vector f 208 for some activity, the relationships between the A_matrix, the B_matrix 204, and the TRACI impacts 202 to obtain a point estimate 210 of CO₂ equivalent emissions. This equation can be shown as:

$$TRACI Impacts \times B \times {A}^{- 1} \times \vec{f} = point estimate . \qquad ( 1 )$$

Using the UPR dataset, each file can be parsed and used to populate the A_matrix and the B_matrix with the appropriate information in order to build the input/output model. Implementing the Input/Output Model

Populating the model and matrices requires three main steps. First, index files are built, where each UPR file is parsed separately for all intermediate exchanges and all elementary changes. Identifying information, numeric values describing interactions, and uncertainty distributions is recorded. After parsing, the parsed files are inserted into a model so that all exchange information is contained in A_matrix (intermediate←→intermediate) and B_matrix (intermediate←→elementary). This provides a record of the direct relationships between all exchanges and their associated uncertainty. For some intermediate exchanges, some output is lost before consumption. For example, some electricity production is lost in transmission before it is consumed by downstream processes. To represent this in an input-output model, reference databases often include scaling factors in the .spold files to represent the lost material. The inputs to the intermediate exchange in question are then scaled up to represent the total amount of inputs required for one unit of usable output after loss (e.g., the amount of material needed to produce 1 unit of electricity after transmission loss). After these steps, the model can be used to calculate climate change impacts (GHG emissions) estimates.

### Building Index Files

The first step is to build files that contain the uniquely identifying information for both intermediate and elementary exchanges. For both types of exchanges, information is parsed and each unique flow is given an integer index. These indices are eventually required to define the (row, column) cell locations within each matrix for the input-output model. These indices are required to define the (row, column) cell locations within each matrix for the input-output model discussed below. Because each integer represents one flow, the (row, column) pairs signify the relationship between one exchange and another within both matrices.

TABLE 1
Intermediate Exchange Index

| activity_id | intermediate_exchange_id | index |
|---|---|---|
| “c1” | “2d” | 0 |
| “n3” | “4p” | 1 |

TABLE 2
Elementary Exchange Index

| subcompartment_id | elementary_exchange_id | index |
|---|---|---|
| “t6” | “5u” | 0 |

### Building Matrices

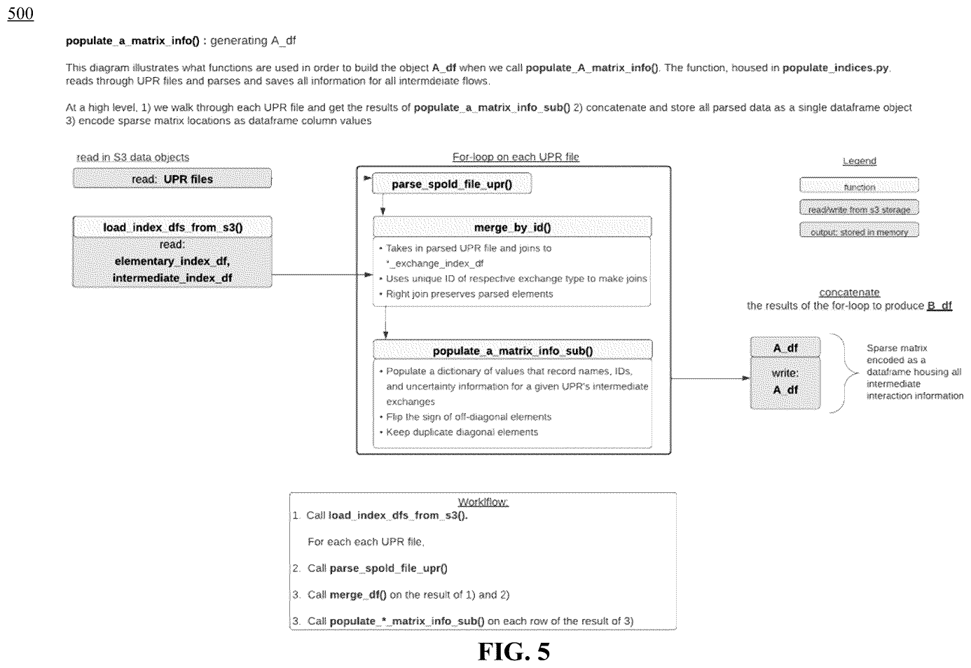

To populate the A_matrix, each .spold file is parsed individually for all intermediate exchanges in that file. An exemplary workflow 500 used to populate the A_matrix is shown in FIG. 5. The parsed .spold file collects unique identifiers (activity_id, intermediate_exchange_id) with other relevant exchange information. The parsed .spold is then merged to the intermediate exchange index file. The result is a single table with three pieces of information for a particular .spold file.
1. Intermediate exchange identifier for the particular .spold file that is parsed;
2. Parsed intermediate exchange data for each of the exchanges inside of the .spold file;
3. An associated index for both the .spold file and each of those flows inside it.

For one .spold file, an object is returned with a constant column index (representing all of the data that resides in the .spold) while the row index is dependent on the unique ID of the flows inside of the reference file. The parsed data in the subsequent columns (coefficient, etc.) are extracted from the parsed file. It should be noted that the coefficient term is not directly parsed from the .spold files. Rather, an element named “amount” is first extracted. The input/output model guidelines then dictate that the amount value changes signs to signify the proper input/output relationship. After this sign change, the transformed amount value is written to the A_matrix as a coefficient.

TABLE 3
Example A Matrix Rows

| row | column | coefficient | uncertainty | mean |
|---|---|---|---|---|
| index | index from | parsed | type | parsed |
| exchange | filename | data | parsed | data |
| (3) | (1) | (2) | data (2) | (2) |
| 1 | 1 | 1 | NaN | NaN |
| 4 | 1 | 0.276 | lognormal | 0.0807 |
| 10 | 1 | 0.98 | none | 0 |
| 17 | 1 | 1.690 | normal | 0.902 |

To populate the full A_matrix, all UPR files are parsed for identifying, numeric, and uncertainty information for all exchanges. Each parsed file is concatenated so that A_matrix houses all intermediate change information.

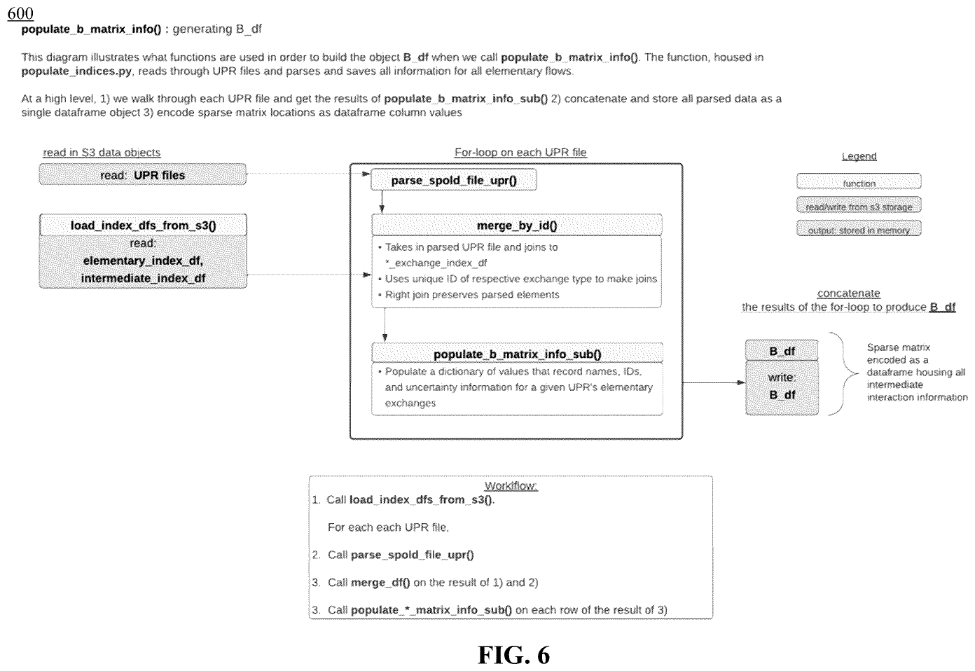

A similar process is followed for elementary exchanges. To populate the B_matrix, each .spold file is parsed individually for all elementary exchanges in that file. An exemplary workflow 600 for populating the B matrix is shown in FIG. 6. As before, there are three pieces of information for a particular .spold file:
1. An intermediate exchange identifier for the particular .spold that is parsed;
2. Parsed elementary exchange data; and
3. An associated index with each of those elementary flows.

For one .spold file, an object can be returned as a table. It should be noted that the rows are now elementary exchanges, as opposed to intermediate exchanges. Further, while there is the same column index (meaning the same .spold file) the parsed information is now representing elementary exchanges. By crawling through the UPR files once again, all parsed .spold files are concatenated into a B_matrix that houses all elementary exchange information.

TABLE 4
Example B Matrix Rows

| row | column | coefficient | uncertainty | mean |
|---|---|---|---|---|
| index | index from | parsed | type | parsed |
| exchange | filename | data | parsed | data |
| (3) | (1) | (2) | data (2) | (2) |
| 2 | 1 | 5.001 | lognormal | 0.0807 |
| 7 | 1 | 0.924 | triangular | 1.4 |

### Scaling A_Matrix

For some intermediate exchanges, some output is lost before consumption. For example, some electricity production is lost in transmission before it is consumed by downstream processes. To represent this in an input-output model, ecoinvent includes scaling factors in the .spold files to represent the lost material. These scaling factors appear to lie on the diagonal of the A_matrix, because they have the same row and column indices, but they are distinguished from elements of A_matrix by the inputGroup and outputGroup tags in the .spold files; diagonal elements of A_matrix have the outputGroup==0 tag whereas scaling factors have the inputGroup==5 tag. The scaling factors are used to preprocess the elements of A_matrix as described below, but are not themselves included in A_matrix.

Consider a table like that output by step 2 (Populating Matrices: A_matrix). This is a compressed and unprocessed format of A_matrix, and is referred to as A_df in the codebase. In an example below, the scaling factor has a coefficient of 0.05. To pre-process the associated exchanges, the present disclosure scales all off-diagonal inputs by dividing them by 1−0.05=0.95 and then removes the scaling factor from the table.

TABLE 5
Example Scaling

| row | column | inputGroup | outputGroup | coefficient | uncertainty type | mean |
|---|---|---|---|---|---|---|
| 2 | 2 | NA | 0 | 1 | NaN | NaN |
| 5 | 2 | 5 | NA | 0.276 | normal | 0.312 |
| 35 | 2 | 5 | NA | 1.4 | uniform | 0 |
| 2 | 2 | 5 | NA | 0.05 | NaN | NaN |

Using mathematical notation, A_matrix is A and has elements of A_matrix Aᵢⱼ, and an additional diagonal entry dᵢ. In a general form, a scaled intermediate exchange generates new a_{scaled,ij} values such that:

$${a}_{scaled , ij} = \frac{{a}_{i j}}{( 1 - {d}_{i} )} \qquad ( 2 )$$

Now, the off-diagonal entries are appropriately scaled to account for the intermediate exchange acting as an input to itself. Using the above table, a worked out example:

$$\begin{matrix}i = 2 \\ {a}_{2 , 2} = 1 \\ {d}_{2} = 0.05\end{matrix} \qquad ( 3 )$$

The non-diagonal exchanges a₂ⱼ:

$$\begin{matrix}{a}_{scaled , 2 , 5} = \frac{0.276}{1 - 0.05} = 0.291 \\ {a}_{scaled , 2 , 3 , 5} = \frac{1.4}{1 - 0.05} = 1.47\end{matrix} \qquad ( 4 )$$

So that the scaled version of the above table after dropping the scaling factor (referred to as A_df_scaled in the code) is:

TABLE 6
Scaled A Matrix

| row | column | inputGroup | outputGroup | coefficient | uncertainty type | mean |
|---|---|---|---|---|---|---|
| 2 | 2 | NA | 0 | 1 | NaN | NaN |
| 5 | 2 | 5 | NA | 0.291 | normal | 0.312 |
| 35 | 2 | 5 | NA | 1.47 | uniform | 0 |

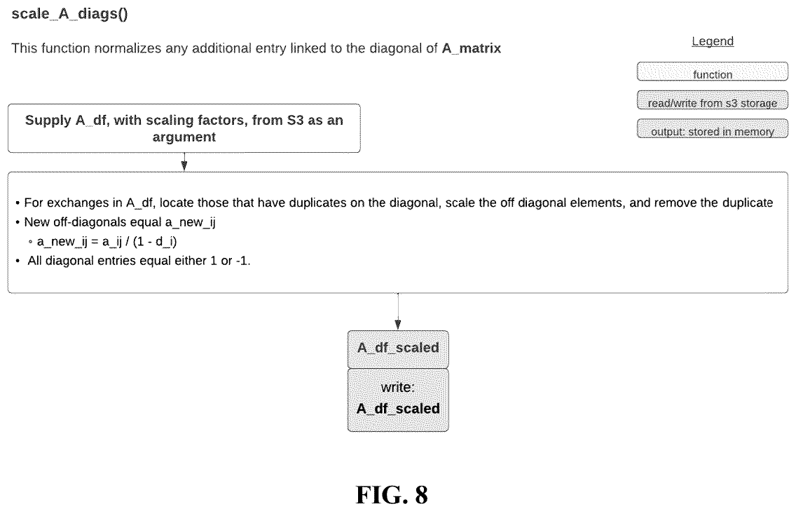

A_df_scaled is then converted to a sparse matrix object to obtain A_matrix. This is also shown in the exemplary method 800 in FIG. 8.

### Scaling B Matrix

When scaling the intermediate exchanges for a process, the process's elementary exchanges must be scaled by the same amount. In particular, if the off-diagonal elements of column j of A_matrix are scaled, the j^{th} column of B_matrix must be scaled by the same amount. To illustrate with an example, let the off diagonal elements in column j=5 of A be scaled by:

$${a}_{scaled , ij} = \frac{{a}_{i j}}{( 1 - {d}_{i} )} \qquad ( 5 )$$

To scale B, the same scaling factor is applied to column 5 of B_matrix:

$${b}_{scaled , ij} = \frac{{b}_{i j}}{( 1 - {d}_{i} )} \qquad ( 6 )$$

### Point Estimates

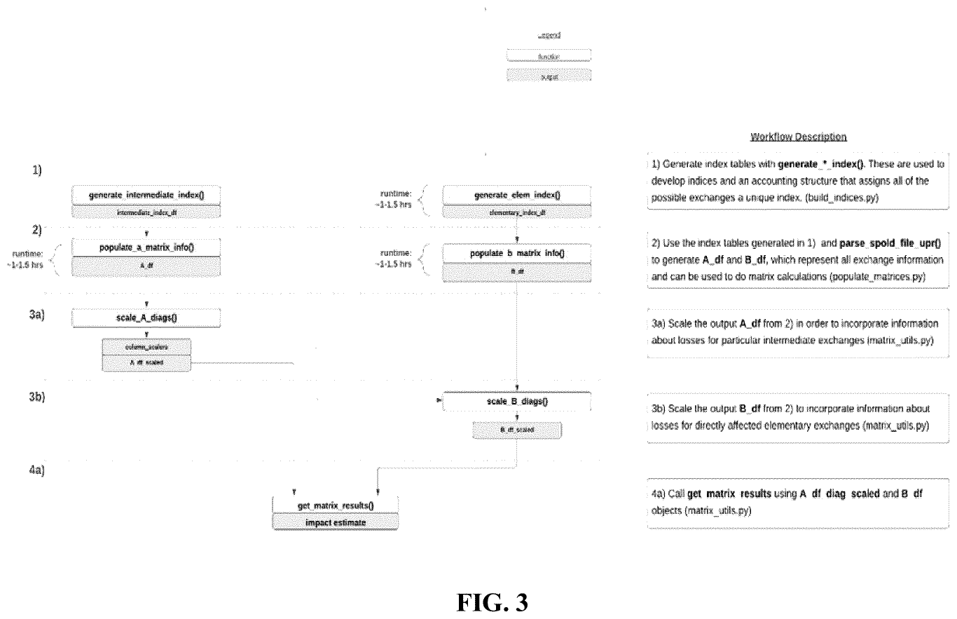

The input/output model estimates a CO2e impact estimate. An exemplary workflow 300 is shown in FIG. 3. This is accomplished by calculating the amount of each intermediate exchange required for a given process (e.g., required to produce 1 kg of ammonia). The amount of elementary exchanges required by those intermediate exchanges is calculated, and then each elementary exchange is converted to CO2e using TRACI conversion factors. Finally, the CO2e impacts are summed across all elementary exchanges to reach a single CO2e impact estimate. To compute a point estimate of equivalent CO₂ impacts, a set of relationships between elementary exchanges and TRACI impact factors are used to generated a single number summary. This is done by compiling all the individual elementary exchange impacts and summing their equivalent CO₂ emissions through one additional matrix operation. The result is a point estimate of overall impact from one intermediate exchange activity. To result in estimates with uncertainty, the above process is used but incorporates uncertainty distributions associated with the individual entries of both A_matrix and B_matrix.

### Internal Calculations

To compute a point estimate, start with demand for some activity of interest. This demand can be represented as a vector and applied to the input/output model. Assume demand vector \vec{f}. Then, to determine how much of each intermediate exchange is required to meet that demand, take the inverse of A_matrix and multiple by \vec{f} (this is also shown in FIG. 2). This results in a scaling factor \vec{s} to understand how much of each associated product is required to meet the demand. So:

$$\vec{s} = {A}^{- 1} \vec{f} \qquad ( 7 )$$

Using the scaling factor, how much of each elementary exchange is required to meet the demand \vec{f} can be computed. B_matrix is then multiplied by the scaling factor to calculate an inventory of elementary flows:

$$\vec{g} = B \vec{s} \qquad ( 8 )$$

Then multiply vector \vec{g} by a C_matrix, where C_matrix contains conversion factors for a particular impact category. Each row of the C_matrix contains conversion factors for a particular impact category (e.g., TRACI 2.1 GWP, or TRACI 2.1 Eutrophication). While it is formally defined as a matrix, embodiments of the present disclosure return impacts for one impact category (TRACI 2.1 GWP). Consequently, C_matrix is a row vector, and the jth element contains the GWP conversion factor for the elementary flow in the jth row of B. Accordingly,

$$impact estiamte = C \vec{g} \qquad ( 9 )$$

If more impact categories are added (e.g., both GWP and Eutrophication), the C_matrix has multiple rows, and the calculation returns a vector of impact estimates.

Uncertainty/Distributional Estimates with Monte Carlo

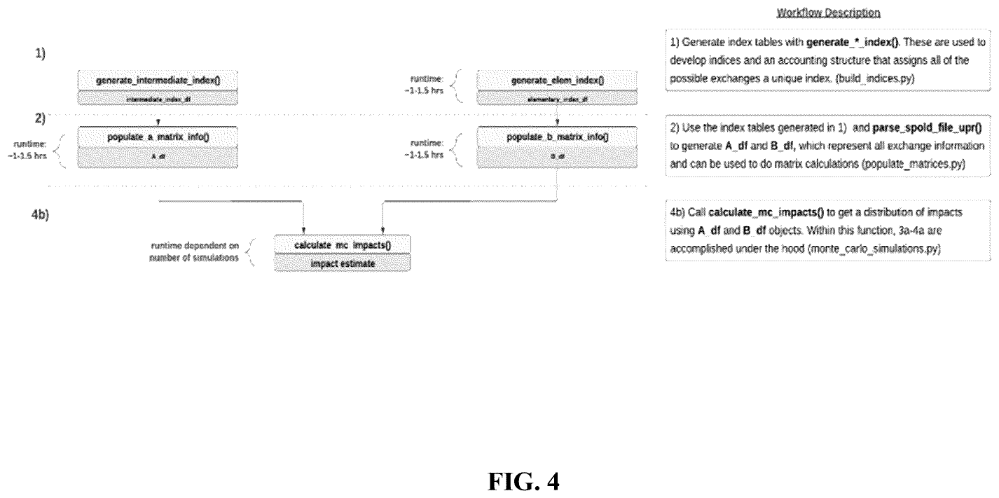

In both the A_matrix and the B_matrix, matrix elements are coefficients that describe the amount of one exchange required by another for each exchange pair. There is also an uncertainty distribution that describes the distribution of that amount. This is illustrated in the exemplary Monte Carlo workflow 400 in FIG. 4.

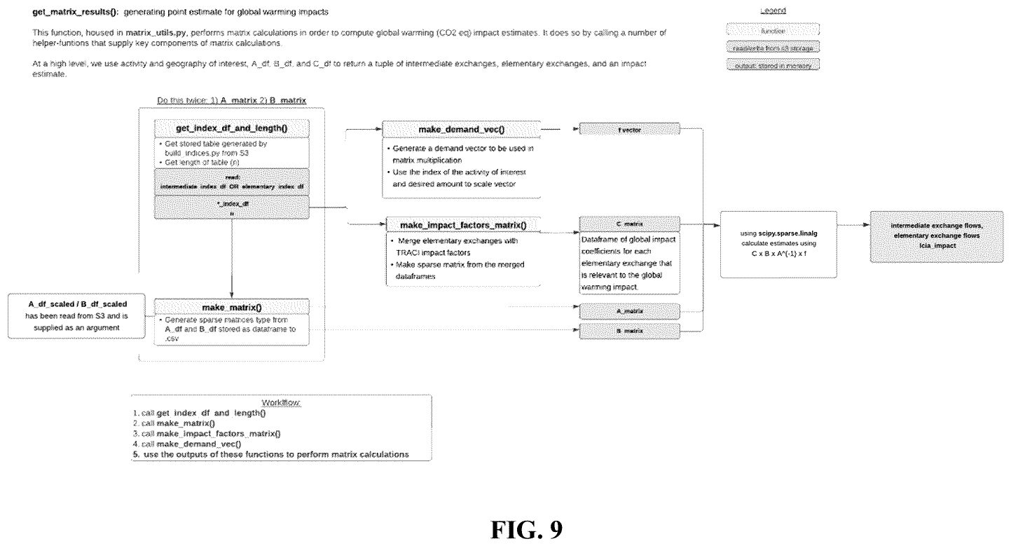

To perform the Monte Carlo simulations, the following steps are performed many times:
1. Draw a value from the distribution associated with each coefficient;
2. Replace the original coefficient with the new sample for each coefficient; and
3. Calculate the point estimate of equivalent CO₂ emissions with the new coefficients.
   An Exemplary Method 900 for Determining the Point Estimate is Shown in FIG. 9. After repeating these steps, the result is a distribution of overall impact for the given demand vector (denoted as f above).
   Estimating Uncertainty with Empirically Generated Distributions

In the UPR .spold files there are five possible uncertainty distributions. These distributions are defined according to their parsed parameters and each of these distributions are used to make random draws:

$$\begin{matrix}log normal ( μ , σ ) \\ normal ( μ , σ ) \\ triangle ( min , median , max ) \\ uniform ( min , max ) \\ undefined\end{matrix} \qquad ( 10 )$$

Given a particular (row, column) pair in a matrix, and an associated uncertainty distribution, a random draw is taken and used to replace coefficient values in both A_matrix and B_matrix. This generates variation in the matrices, which can be called A_matrix_new and B_matrix_new.

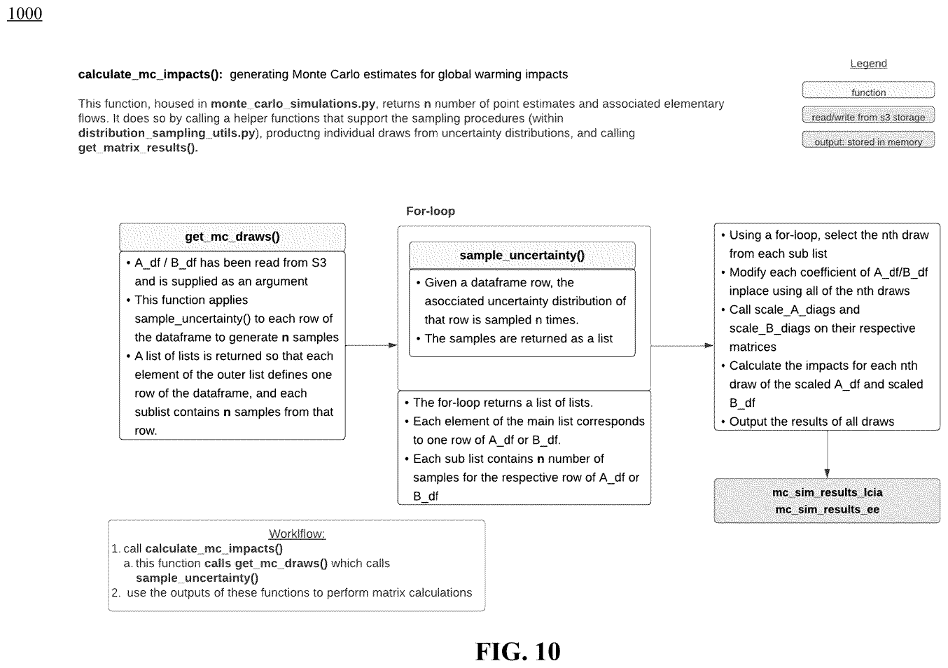

For each simulation of a Monte Carlo run, A_matrix_new and B_matrix_new are used to calculate point estimates of TRACI impacts for a particular activity of interest. From many simulations, we get an empirical distribution of impacts. The distribution for reporting uncertainty can then be summarized, e.g., using the standard deviation and the 10th and 90th percentiles. An exemplary method 1000 of determining the Monte Carlo estimate is shown in FIG. 10.

### Discrepancies Between Deterministic and Monte Carlo Results

The mean TRACI impacts from MC simulations will, by design, never be equal to the deterministic point estimate obtained without MC simulations. For exchanges defined by lognormal and triangular distributions, the deterministic point estimate does not use the arithmetic mean of those distributions. For exchanges with lognormal distributions, ecoinvent sets the deterministic exchange amount to the geometric mean, and for the triangular distribution ecoinvent sets the deterministic exchange amount to the mode.

There are about 1,000 times more exchanges with a log-normal distribution than any other single distribution in the A matrix, and about 100 times more than any other single distribution in the B matrix. Because the arithmetic mean is greater or equal to the geometric mean, and the deterministic amounts are set to the geometric mean for exchanges with log-normal distributions, the arithmetic mean of the LCIA impacts from MC simulations tend to be larger than the deterministic LCIA impacts. Said another way, the randomly generated A and B matrices, the amount of material required for production tends to be larger than in the deterministic A and B matrices, which leads to greater GHG emissions.

### Potential Approaches to Reconcile Deterministic and Monte Carlo Simulation Results

In some embodiments, steps are taken to reconcile deterministic and Monte Carlo simulation results, which:
(a) Update the distributions so that the arithmetic means are always equal to the amounts used in deterministic calculations, or
(b) Update the amount used in deterministic calculations to match the arithmetic mean of the corresponding distribution.

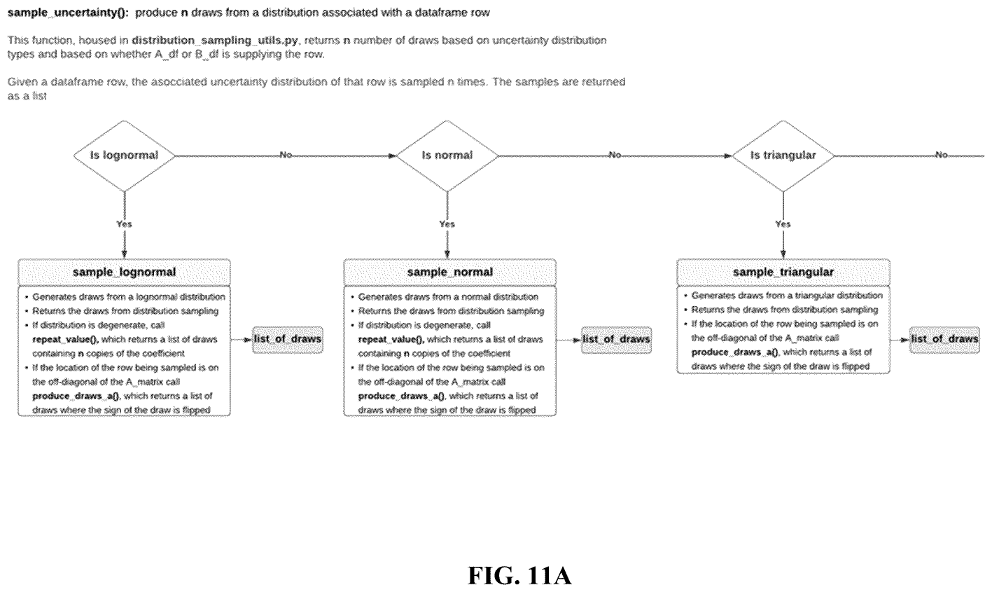

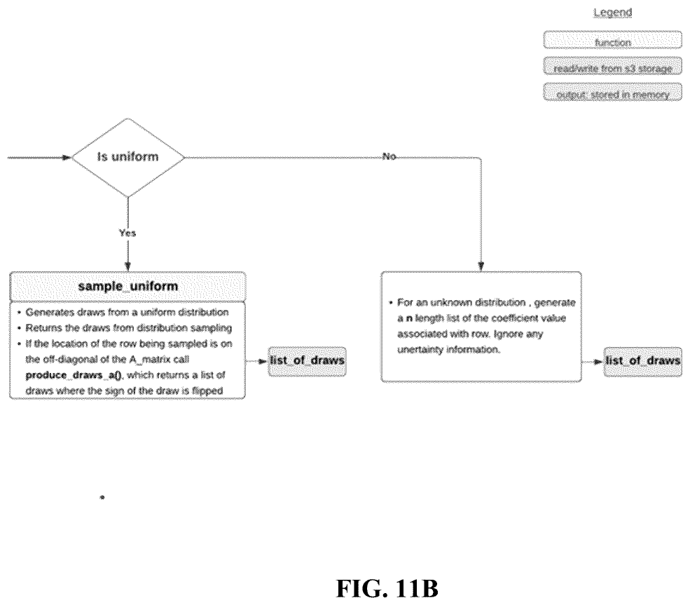

An example based on 1 is further shown in FIGS. 11A and 11B, by exemplary method 1100.

Ecoinvent provides the following parameters for the log-normal distribution:
(a) Geometric mean μ_{geo}; and
(b) Variance of the underlying normal distribution σ²

The deterministic calculation is done with the amount value in the .spold files, and amount=μ_{geo}. To implement 1 for lognormal distributions with non-zero (and non-null) variance, one approach is to:
(a) Assume that the amount was intended to represent the arithmetic mean and treat the provided variance as fixed; and
(b) Solve for the geometric mean

$${μ}_{g e o} = {μ}_{arith} * exp ( - \frac{{σ}^{2}}{2} )$$

(from inverting the formula for the mean).

It is complemented that Approach 1 can be implemented in a similar fashion for triangular distribution.

The intended uses include, but are not limited to, planning, experimentation, and build-out of Scope 3 programs for consumer packaged good (CPG) companies; investigating effect size of individual agronomic inputs; and to run in combination with carbon emissions database programs to get a complete view of emissions without double-counting or omitting sources.

Embodiments of the present disclosure do not require a complete life cycle assessment (LCA). An LCA includes four essential phases: goal and scope definition, inventory analysis, impact assessment, and interpretation. Embodiments of the present disclosure are designed with an underlying set of assumptions using LCA methodology and documentation for all four phases in progress. However, users that make any changes to the model's approach or aggregate results for ecosystem crediting or sustainability program use (e.g., project-minus-baseline, or aggregating full crop rotations) may need to generate individual LCA documentation, because these changes would impact all four phases of that particular LCA.

In order to accurately produce a greenhouse gas inventory model, two factors must be addressed. The first is performance. Computing emissions for a single activity takes 1-3 seconds using exemplary IO model matrices (mainly to solve a ˜20k×˜20k sparse matrix equation). A reasonable sample size of ˜500 random samples will take on the order of 10 minutes. To further complicate the issue, each agronomic event can include multiple activities. The second issue that arises is granularity and aggregation. The current approach for computing event emissions is to sum the contributions of the activities that comprise that event. Unfortunately, aggregating uncertainty is not so straightforward. If each activity's emissions is thought of as a random variable, and using variance as the uncertainty metric, the uncertainty can be aggregated as:

$$Var ( {\sum }_{i = 1}^{n} {X}_{i} ) = {\sum }_{i = 1}^{n} Var ( {X}_{i} ) + {\sum }_{\begin{matrix}i , j = 1 \\ i \neq j\end{matrix}}^{n} Cov ( {X}_{i} , {X}_{j} ) == {\sum }_{i = 1}^{n} {\sum }_{j = 1}^{n} Cov ( {X}_{i} , {X}_{j} ) \qquad ( 11 )$$

The activity emissions samples will be correlated across activities because each activity emissions must be computed using the same randomly sampled input-output matrix. Thus, variance cannot be computed without accounting for this correlation. A single event may comprise multiple activities. In some applications, multiple events must be aggregated to produce emissions with uncertainty for one or more identified geographic regions (such as an agricultural field, a county, a state, etc.) and/or entities (for example, a company, a division of a company, a producer of a consumer product, a farming operation, or sustainability program, etc.). To accurately deal with correlated and non-correlated activities, the program decomposes the problem to look at each activity separately. When there is a covariance of zero (i.e., the activities are not correlated), statistics describing those activities can be directly computed without reference to other activities. Each sample of each activity requires computation using the same coefficients. To perform this computation, the process includes the steps of: precomputing all samples; combining the samples on a one-to-one basis; and then allowing the samples to remain correlated or shuffling the samples to suppress correlation.

For example, two fertilizers can be produced in similar factories. It is possible that one production uses more electricity, or both use the same amount of electricity based on similar environmental factors. Here, the covariance term between these activities can increase uncertainty, which should not be underreported. After saving many samples of each activity, the emissions for these are made arbitrary. Then, computing emissions for an arbitrary combination of activities will still yield a correct uncertainty value.

In some embodiments, a vector of all demanded activities (also referred to as a demand vector) is used. A series of linear equations is solved to determine demand, which is converted to an emissions value. Solving the linear equations can be done by looking up the values for the activities and recombining these values. The number of activities and events are used as weights within the demand vector. In solving the linear system of equations, a way to calculate combination of any arbitrary linear combination of products is needed, in a way that preserves correlation across the matrices that are being solved.

Certain available models compute point estimates for random variables differently for different underlying distributions. This choice means that the arithmetic mean of a set of random samples may not match the database's reported estimate.

The requirements for the greenhouse gas inventory model can include the following. Any result that can include uncertainty must include uncertainty (i.e., event emissions, activity emissions, etc. Per-activity emissions must be reported as well as per-event emissions. Aggregation should be supported at higher levels: aggregating multiple events to get field emissions with uncertainty, and aggregating multiple fields to get “program” emissions with uncertainty. Random samples for different activities should use the same random coefficients. The samples should be correlated. Point estimates and uncertainties should be approximately equal to those provided by a database at the activity level. Additionally, the model must run at a usable speed. A target speed would be less than 10 seconds per field, which implies less than one second per event and much less than one second per activity.

### Precomputation of Activity Emissions Samples

To ensure the process computes at a sufficiently practical speed, activity emissions are precomputed and saved as tables within the computer program. For example, emissions from tilling a hectare in a given geographic location can be saved, and specific weights and values can add value to the computation. The saved values are then looked up prior to running the model, which cuts down on processing time.

The input to this phase is the parsed activity information table which includes activity IDs, point estimates, and uncertainty distribution definitions. The output from this phase is a file containing pre-computed emissions samples for each activity (or, optionally, for only those that are directly demanded by event mappings), in the form of a list of XML files.

The precomputing step is separated into two steps: generating the IO model matrices, and generating activity emissions samples using these matrices. The advantage of splitting the process into two steps instead of handling both steps together is to be able to accommodate future expansion of the list of activities, and this pre-computation step may be costly. Saving the matrices allows for the addition of a single activity later on using the same random samples, instead of having to recompute all activities each time a new one is added.

In some embodiments of the present disclosure, separate sample runs are created and then combined later to form an aggregation of matrices. All samples are stored within this phase of the process, so each can be treated as correlated or uncorrelated, depending on the situation. The samples can be stored within the application as tables, from which values are looked up and then the model is run.

Generating and Saving IO-Model Matrices with Randomly Sampled Coefficients

In exemplary embodiments, an “update-io-matrices” function is defined. This function performs the following:
Read in the activity information (e.g., from a CSV containing activity definitions and uncertainty distributions)
Generate a unique Model ID to identify this set of randomly-sampled matrices (e.g., using a UUID)
Repeat for some suitably large N:
   Generate randomly sampled A, B, and c matrices
Save these matrices for reuse (e.g., in cloud storage such as S3).

In various embodiments, saved IO matrices are frozen, such that the editing or extending of an existing set of IO matrices is prohibited. If it were to be supported, the ID would not uniquely identify the model coefficients. The data can be stored remotely, to account for the large size of the dataset. One set of IO matrices saved, for example, as a compressed.npz file is roughly 10 MB, so N sets of IO matrices is likely too large to store locally.

### Computing Random Samples of Activity Emissions

In exemplary embodiments, an “update-activity-emissions” function is defined. This function has an optional Model ID as input, which will default to a constant references in the greenhouse gas inventory model library proper. The existing activity samples are loaded, if they exist, for the specified model ID. This yields a list of “ActivityEmissions” objects (see below for how this class is modified to store samples). The CLI then loops over all enumerated activities, for each activity. If there is already a result for the activity and model ID, it can be skipped during the looping step, to avoid recomputation. If there is not yet a result, the CLI loops over the N stored IO-matrices and computes the emissions using each sample. An array is accumulated of the calculated emissions and an “ActivityEmissions” object is created for the activity. The new result is appended. After completing all activities, the updated activities are saved to S3 in a single file “ggim_model_<ID>_activities.blah”.

### Including Emissions Samples in Results Classes

The tables below show the required features and how each is implemented in an exemplary embodiment.

TABLE 7
Activity Emissions
Activity Emissions

| Requirement | Implementation |
|---|---|
| Store a list of samples for | private attribute for samples, _co2eq_kg_samples: |
| emissions results | tuple[float] |
| Store the model ID used to | private attribute for this ID, _io_model_id: str |
| calculate those samples | |
| Compute the best-estimate CO2eq | Either make co2eq_kg a property or define a default |
| from the samples | function for it. The best-estimate will be computed as the |
| | mean of the samples. |
| Compute uncertainty (standard | std_co2eq_kg property or attribute-with-default. The |
| deviation) for CO2eq from the | standard deviation will be computed from the stored |
| samples | sample array. |
| Support scaling to a new amount | method, to_amount(self, amount: float) −> |
| (so that we can rescale stored | ActivityEmissions, which “evolves” the object and |
| results to the demanded activity | returns a copy with an updated amount, |
| amounts) | _co2eq_kg_samples, and co2eq_kg |

TABLE 8
Event Emissions
EventEmissions

| Requirement | Implementation |
|---|---|
| Store a list of samples for | private property or attribute for samples, |
| emissions results. | _co2eq_kg_samples: tuple[float], computed as the |
| | element-wise sum of the sampled activity emissions. |
| Store the model ID used to | private attribute for this ID, _io_model_id: str. Include a |
| calculate those samples | validation check that this matches the ID on all of the |
| | embedded activity emissions. |
| Compute the best-estimate | Either make co2eq_kg a property or define a default function |
| CO2eq from the samples | for it. The best-estimate will be computed as the mean of the |
| | samples. |
| Compute uncertainty (standard | std_co2eq_kg property or attribute-with-default. The |
| deviation) for CO2eq from the | standard deviation will be computed from the stored sample |
| samples | array. |

Further aggregations to field or program level are possible by following the same pattern used for activities.
(c) Reading Pre-computed Activity Emissions at Runtime
(d) At model runtime, the saved activity emissions samples are read and scaled up to the requested activity amounts. This is accomplished by obtaining the active Model ID (defined as a constant), then loading the pre-computed activities for the active models. Next, the activity of interest is found in the loaded list, and the code calls the new “.to_amount” method to scale it up to the requested amount. The code then returns to the starting position.

### Methods

### System Boundary

Generally, embodiments of the present disclosure account for all pre-field and some on-field emissions of individual agronomic events. The system boundary (model boundary) is intended to exclude on-field emissions modeled by an alternative emissions model and include all other emissions sources, so the two models can be run in combination without “double counting”. For each agronomic event type, details of emissions sources, and therefore system boundary, slightly vary.

### Emissions Database

Embodiments of the present disclosure can be built on an emissions database or model, such as ecoinvent. Specifically, embodiments can use the “Allocation, cut-off by classification” database and the “Life Cycle Inventory” structure of the ecoSpold2 files, version 3.8 (release date: Sep. 21, 2021). Ecoinvent is a life cycle inventory database and provides emissions estimates for all emission types, not just greenhouse gas emissions. Within greenhouse gas emissions, ecoinvent provides data on all seven major gases from the Kyoto protocol and more. Embodiments of the present disclosure can use ecoinvent process data as-is and do not modify any individual processes. In addition, as noted above, the present disclosure may use any of a variety of alternative databases or models, including alternative databases or models for emissions data.

### Impact Assessment Method

Embodiments of the present disclosure use the Environmental Protection Agency's (EPA) Tool for Reduction and Assessment of Chemicals and Other Environmental Impacts to convert emissions of a wide range of substances to the equivalent amount of CO2.

### Supported Agronomic Events

Embodiments of the present disclosure includes, but is not limited to, the following agronomic events. The below table summarizes exemplary agronomic events and emissions sources. Other agronomic events and emissions sources are also possible. Impact quantification methods described herein may be used to quantify all or some pre-field, on-field, post-field agronomic events. Impact quantification methods described herein may be used in conjunction with other quantification methods, for example, one or more biogeochemical models, machine learning models, etc. Notably, in some example embodiments, various emission sources may be included or excluded based on the configuration of the models and/or dataset. handled by a single model.

TABLE 9
Example Agronomic Events

| Agronomic event | Emissions sources |
|---|---|
| Fertilizer (production and | production of chemicals |
| application) | transportation emissions from production |
| | market diesel production (application) |
| | direct combustion of diesel(application) |
| | production of tractor & equipment |
| | soil-based emissions (SOC, direct/indirect |
| | N2O, CH4, etc) |
| Tillage | diesel production |
| | direct combustion of diesel |
| | production of tractor & equipment |
| | soil-based emissions (SOC, direct/indirect |
| | N2O, CH4, etc) |
| Irrigation | energy source (electricity/diesel) production |
| | direct combustion (if diesel energy source) |
| | production of equipment |
| | soil-based emissions (SOC, direct/indirect |
| | N2O, CH4, etc) |
| Planting | diesel production |
| | direct combustion of diesel |
| | production of tractor & equipment |
| | seed being planted |
| | soil-based emissions (SOC, direct/indirect |
| | N2O, CH4, etc) |
| Harvest | diesel production |
| | direct combustion of diesel |
| | production of tractor & equipment |
| | soil-based emissions (SOC, direct/indirect |
| | N2O, CH4, etc) |

Embodiments of the present disclosure can be implemented as a Python shared library. A user can either install the library and write a script to invoke it, or run the model via other workflow tools.

Embodiments of the present disclosure can handle individual agronomic events, meaning that a complete crop rotation is not required for the model to function. Along these lines, a user can run “baseline” years, and “project” years for individual agronomic events to gather effect size. However, it is noted that certain preprocessing steps may require a full crop growing season for accurate reporting.

### Model Inputs

The input to exemplary embodiments of the present disclosure is a set of agronomic events. These events can be provided as, e.g., either (a) event summary objects, or (b) event data contract objects. It is considered that other data formats could be used in the model.

For the examples below, the input variables are “ads_events”, a tuple of ADS event contracts, and “ggim_events” a tuple of equivalent model event summaries.

### Model Inputs

### Example Event Boundary

A ˜30 hectare farm somewhere in Ohio can be input as the following:
farm_centroid=shapely.wkt.loads(‘POINT (−82.658265 40.285918)’)
farm_boundary=farm_centroid.buffer(0.0032).simplify(0.0005)

### Example ADS Event Contracts

An ADS event contract can be provided as follows:

```
ads_events = (
  ConcreteTillage(
  event_id=‘1’,
  start=date(2022, 1, 1),
  end=None,
  geometry=farm_boundary,
  equipment=None,
  method=TillageMethod.MOLDBOARD,
  ),
  ConcreteChemicalApplication(
  event_id=‘2’,
  start=date(2022, 2, 2),
  end=None,
  geometry=farm_boundary,
  method=ChemicalApplicationMethod.SURFACE,
  blend_components=(
  ConcreteChemicalApplicationComponent(
  product=ConcreteChemicalProduct(
  nitrogen_forms=(
  ConcreteNitrogenForm(nitrogen_form=NitrogenForm.UREA),
  ),
  macronutrient_nitrogen=50.0,
  ),
  rate_kg_per_ha=100.0,
  ),
  )
  )
)
```

### Model Event Summaries

These event summaries represent the same agronomic events as the ADS Event Contracts, just in a native format. For example:

```
lcia_events = (
  LciaTillageSummary(
  event_id=‘1’,
  geometry=farm_boundary,
  start=date(2022, 1, 1),
  warnings=tuple( ),
  method=TillageMethod.MOLDBOARD,
  equipment=None
  ),
  LciaChemicalApplicationSummary(
  event_id=‘2’,
  start=date(2022, 2, 2),
  geometry=farm_boundary,
  warnings=tuple( ),
  blend_components=(
  LciaChemicalApplicationComponentSummary(
  npks=FertilizerComposition(N=0.5),
  nitrogen_forms={NitrogenForm.UREA},
  rate_kg_per_ha=100.0,
  rate_l_per_ha=None,
  ),
  ),
  method=ChemicalApplicationMethod.SURFACE
  ),
)
```

### Model Outout

The model returns a Results object containing the calculated emissions for each input event as a list of EventEmissions objects. Each EventEmissions object reports the emissions for the event in kg CO2-equivalent, and contains the emissions contribution of the individual ecoinvent “activities” for that event as a list of ActivityEmissions objects. For example:

```
{
  “@class”: “Results”,
  “completed_at”: “2023-01-27T15:18:56.391017+00:00”,
  “event_emissions”: [
  {
  “@class”: “EventEmissions”,
  “activities”: [
  {
  “@class”: “ActivityEmissions”,
  “activity”: “market for tillage, ploughing”,
  “amount”: 27.348339629232886,
  “co2eq_kg”: 3310.1216391578932,
  “geography”: “GLO”,
  “warnings”: [ ]
  }
  ],
  “area_ha”: 27.348339629232886,
  “co2eq_kg”: 3310.1216391578932,
  “event_id”: “1”,
  “event_type”: “tillage”,
  “harvest_yield”: null,
  “start_date”: “2022-01-01”,
  “warnings”: [ ]
  },
  {
  “@class”: “EventEmissions”,
  “activities”: [
  {
  “@class”: “ActivityEmissions”,
  “activity”: “market for fertilising, by broadcaster”,
  “amount”: 27.348339629232886,
  “co2eq_kg”: 705.0938422169655,
  “geography”: “GLO”,
  “warnings”: [ ]
  },
  {
  “@class”: “ActivityEmissions”,
  “activity”: “market for inorganic nitrogen fertiliser, as N”,
  “amount”: 1367.4169814616444,
  “co2eq_kg”: 7043.729682951965,
  “geography”: “US”,
  “warnings”: [ ]
  },
  {
  “@class”: “ActivityEmissions”,
  “activity”: “packaging production for solid fertiliser or pesticide, per
kilogram of packed product”,
  “amount”: 2734.8339629232887,
  “co2eq_kg”: 26.235704151404544,
  “geography”: “GLO”,
  “warnings”: [ ]
  }
  ],
  “area_ha”: 27.348339629232886,
  “co2eq_kg”: 7775.059229320334,
  “event_id”: “2”,
  “event_type”: “chemical_application”,
  “harvest_yield”: null,
  “start_date”: “2022-02-02”,
  “warnings”: [ ]
  }
  ],
  “logs”: [ ],
  “version”: “1.0.0”
```

Users may be interested in the equivalent greenhouse gas emissions for each event. The model leaves the rest of the interpretation up to the user, as it is likely to be application specific. For example, the per-event emissions can be summed up to give total emissions for a field, emissions per area (divide by total acres or hectares), or by cash crop harvest yield (divide by “crop_yield”).

A few attributes are left out here for readability. The full results objects include warnings and logs for visibility into how model calculations were done, and for debugging when things go wrong. Most users can happily ignore them—it is normal to have some warning messages even when the model runs successfully and correctly.

### Example Model Inputs

Embodiments of the present disclosure consume agronomic activities in various formats. An agronomic activity is a collection of agronomic events and (optionally) on-field measurements. In certain embodiments of the present disclosure, only the agronomic events are consumed, ignoring any measurements. Agronomic activities may be defined as YAML. An example is shown below.

```
  “name”: “GGIM Demo 2023-01-27”,
  “summary”: “An example agronomic activity.”,
  “practice_change_date”: null,
  “tags”: [
  “example”,
  “GGIM”,
  ],
  “measurements”: [ ],
  “agronomic_events”: [
  {
  “start_date”: “2020-08-22”,
  “end_date”: “2020-08-22”,
  “geometry_wkt”: “POLYGON((−85.3170336641044 40.215018753195714, −
85.31699309569305 40.215018753195714, −85.31699309569305 40.21500211151414, −
85.3170336641044 40.21500211151414, −85.3170336641044 40.215018753195714))”,
  “type”: “harvest”,
  “yield_kg_ha”: 30.0,
  “is_burn”: “false”,
  “method”: “grain_only”
  },
  {
  “start_date”: “2020-06-01”,
  “end_date”: “2020-07-01”,
  “geometry_wkt”: “POLYGON((−85.3170336641044 40.215018753195714, −
85.31699309569305 40.215018753195714, −85.31699309569305 40.21500211151414, −
85.3170336641044 40.21500211151414, −85.3170336641044 40.215018753195714))”,
  “type”: “planting”,
  “crop”: “barley”,
  “is_cover_crop”: “false”
  },
  {
  “start_date”: “2020-11-03”,
  “end_date”: “2020-11-03”,
  “geometry_wkt”: “POLYGON((−85.3170336641044 40.215018753195714, −
85.31699309569305 40.215018753195714, −85.31699309569305 40.21500211151414, −
85.3170336641044 40.21500211151414, −85.3170336641044 40.215018753195714))”,
  “type”: “tillage”,
  “method”: “finisher”,
  “equipment”: “soil_finisher”
  },
  {
  “start_date”: “2020-05-25”,
  “end_date”: “2020-05-25”,
  “geometry_wkt”: “POLYGON((−85.3170336641044 40.215018753195714, −
85.31699309569305 40.215018753195714, −85.31699309569305 40.21500211151414, −
85.3170336641044 40.21500211151414, −85.3170336641044 40.215018753195714))”,
  “type”: “chemical_application”,
  “rate_kg_ha”: 10,
  “fertilizer_product”: “Ammonium Nitrate (34-0-0)”,
  “n_fraction”: 0.34,
  “p2o5_fraction”: 0.00,
  “k2o_fraction”: 0.00,
  “nitrate_fraction”: 0.50,
  “ammonium_fraction”: 0.50,
  “is_slow_release”: “false”,
  “is_nitrification_inhibitor”: “false”,
  “is_urea_inhibitor”: “false”
  },
  {
  “start_date”: “2020-06-02”,
  “end_date”: “2020-06-05”,
  “geometry_wkt”: “POLYGON((−85.3170336641044 40.215018753195714, −
85.31699309569305 40.215018753195714, −85.31699309569305 40.21500211151414, −
85.3170336641044 40.21500211151414, −85.3170336641044 40.215018753195714))”,
  “type”: “irrigation”
  }
  ]
}
```

The example activity can be uploaded and assigned an ID for the newly stored agronomic activity in response.

### Model Execution

Upon running the model, the user obtains a simulation ID to fetch the results. A typical model run takes only a few seconds to complete.

### Model Outputs

Model results are returned formatted as a JSON file. The results can be retrieved based on the simulation ID. This returns a URL that can be used to download the results file.

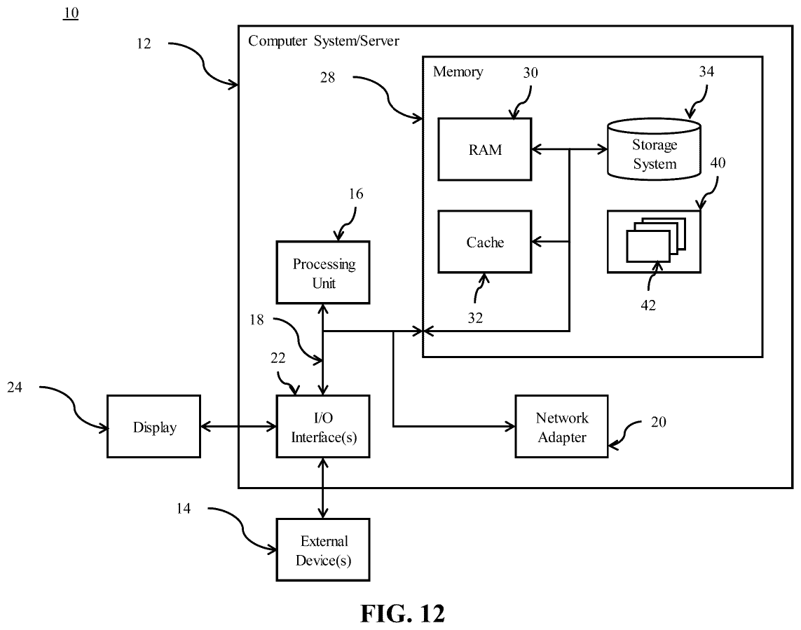

Referring now to FIG. 12, a schematic of an example of a computing node is shown. Computing node 10 is only one example of a suitable computing node and is not intended to suggest any limitation as to the scope of use or functionality of embodiments described herein. Regardless, computing node 10 is capable of being implemented and/or performing any of the functionality set forth hereinabove.

In computing node 10 there is a computer system/server 12, which is operational with numerous other general purpose or special purpose computing system environments or configurations. Examples of well-known computing systems, environments, and/or configurations that may be suitable for use with computer system/server 12 include, but are not limited to, personal computer systems, server computer systems, thin clients, thick clients, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system/server 12 may be described in the general context of computer system-executable instructions, such as program modules, being executed by a computer system. Generally, program modules may include routines, programs, objects, components, logic, data structures, and so on that perform particular tasks or implement particular abstract data types. Computer system/server 12 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 12, computer system/server 12 in computing node 10 is shown in the form of a general-purpose computing device. The components of computer system/server 12 may include, but are not limited to, one or more processors or processing units 16, a system memory 28, and a bus 18 that couples various system components including system memory 28 to processor 16.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, Peripheral Component Interconnect (PCI) bus, Peripheral Component Interconnect Express (PCIe), and Advanced Microcontroller Bus Architecture (AMBA).

Computer system/server 12 typically includes a variety of computer system readable media. Such media may be any available media that is accessible by computer system/server 12, and it includes both volatile and non-volatile media, removable and non-removable media.

System memory 28 can include computer system readable media in the form of volatile memory, such as random access memory (RAM) 30 and/or cache memory 32. Computer system/server 12 may further include other removable/non-removable, volatile/non-volatile computer system storage media. By way of example only, storage system 34 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 18 by one or more data media interfaces. As will be further depicted and described below, memory 28 may include at least one program product having a set (e.g., at least one) of program modules that are configured to carry out the functions of embodiments of the disclosure.

Program/utility 40, having a set (at least one) of program modules 42, may be stored in memory 28 by way of example, and not limitation, as well as an operating system, one or more application programs, other program modules, and program data. Each of the operating system, one or more application programs, other program modules, and program data or some combination thereof, may include an implementation of a networking environment. Program modules 42 generally carry out the functions and/or methodologies of embodiments as described herein.

Computer system/server 12 may also communicate with one or more external devices 14 such as a keyboard, a pointing device, a display 24, etc.; one or more devices that enable a user to interact with computer system/server 12; and/or any devices (e.g., network card, modem, etc.) that enable computer system/server 12 to communicate with one or more other computing devices. Such communication can occur via Input/Output (I/O) interfaces 22. Still yet, computer system/server 12 can communicate with one or more networks such as a local area network (LAN), a general wide area network (WAN), and/or a public network (e.g., the Internet) via network adapter 20. As depicted, network adapter 20 communicates with the other components of computer system/server 12 via bus 18. It should be understood that although not shown, other hardware and/or software components could be used in conjunction with computer system/server 12. Examples, include, but are not limited to: microcode, device drivers, redundant processing units, external disk drive arrays, RAID systems, tape drives, and data archival storage systems, etc.

The present disclosure may be embodied as a system, a method, and/or a computer program product. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

The node of FIG. 12 may be present in a system environment that enables generating an aggregated impact value for an agronomic event.

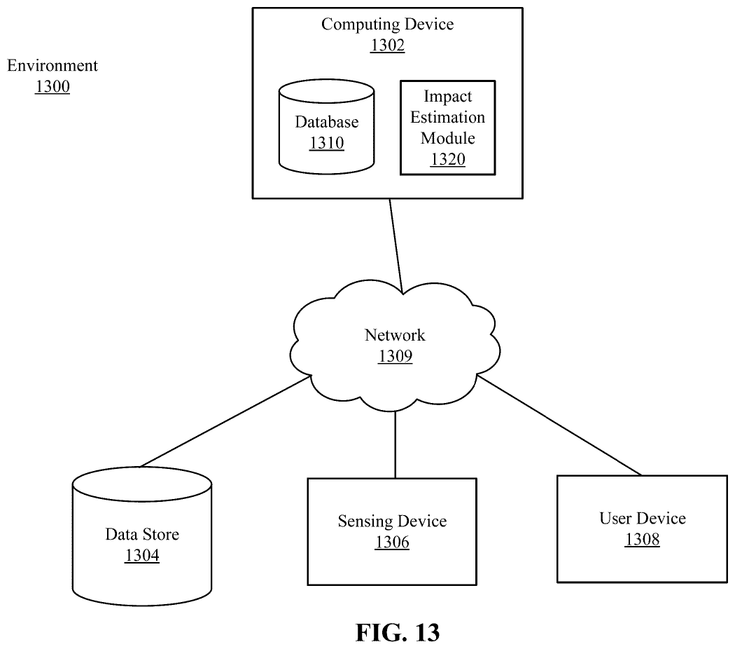

FIG. 13 is a block diagram that illustrates an ecosystem management environment, according to embodiments of the present disclosure. The ecosystem management environment (“environment”) 1300 includes a computing device 1302, a data store 1304, a sensing device 1306, a user device 1308, and a network 1309. The entities and components in the ecosystem management environment 1300 may communicate with each other through a network 1309.

In various embodiments, the ecosystem management environment 1300 includes fewer or additional components. In some embodiments, the ecosystem management environment 1300 also includes different components. While each of the components in the ecosystem management environment 1300 is described in a singular form, the ecosystem management environment 1300 may include one or more of each of the components. For example, in many situations, the computing device 1302 may receive information form a plurality of sensing devices 1306. Different user devices 1308 may also access the computing device 1302 simultaneously.

The computing device 1302 may include one or more processors/computers (e.g., computing node 10 of FIG. 12) that perform various tasks related to ecosystem management. In some embodiments, the computing device 1302 includes a database 1310 and an impact estimation module 1320. The computing device 1302 may receive data from one or more data sources through the data store 1304, the sensing device 1306, user device 1308, and/or the network 1309.

At a high level, the computing device 1302 receives a request from, e.g., a user device 1308 to generate an impact value for an agronomic event in one or more agronomic regions. An agronomic event is one or more processes that occur in an agronomic region (e.g., a field) related to the production of agronomic output. As an example, an agronomic event may be tilling a field to produce corn. An impact value is a quantification of various ecosystem attributes that correspond to the agronomic event. More simply, the impact value quantifies a degree to which the particular agronomic event affects the environment on a whole or an aspect of the environment (e.g., an ecosystem attribute). That is, the impact value may quantify a total amount of carbon emissions associated with the tilling the field to produce corn (either in absolute or relative terms).

Remaining at a high level, to determine the impact value, the computing device 1302 receives a request from a user device 1309 to generate an impact value for an agronomic event in an agronomic region or regions. The request may include, e.g., the agronomic event, the agronomic regions, information from the datastore 1304, sensing device 1306, and user device 1308 that may affect the impact estimation. That information may include, a series of activities that the user performed in the agronomic region when performing the agronomic event, one or more historic activities or agronomic events performed in the field, environmental conditions of the field, additional agronomic conditions of the field including, e.g., material used, weather, etc.

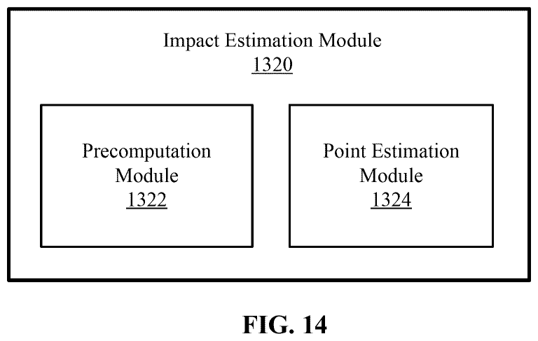

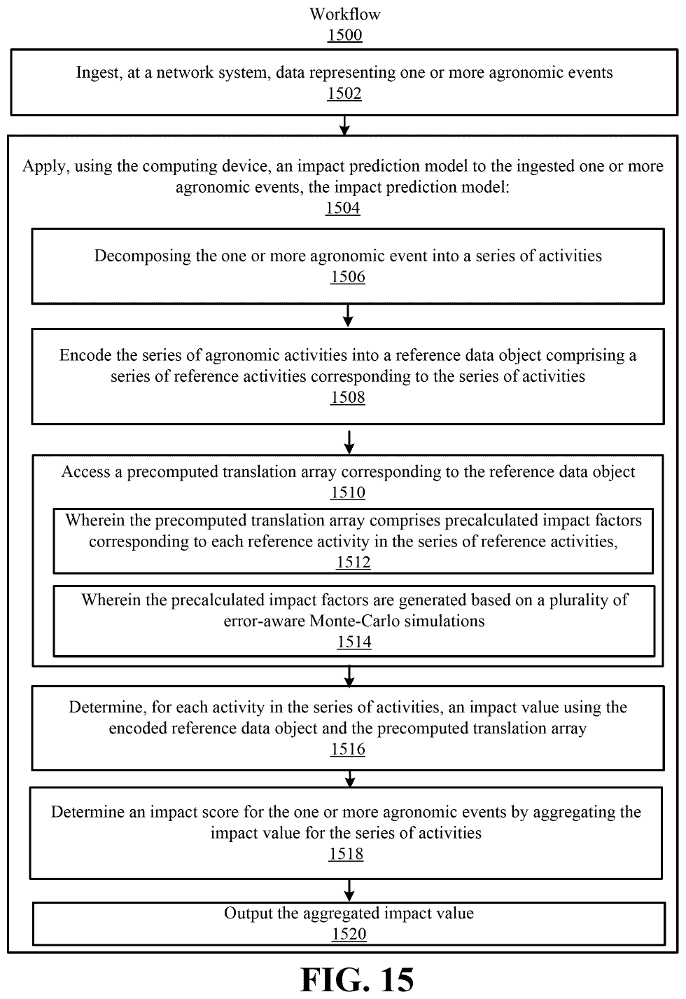

The computing device 1302 employs the impact estimation module 1320 to determine the impact value for the agronomic event in the agronomic region. The impact estimation module 1320 applies a model that generates various data structures that represent the agronomic event and translates the agronomic event into an impact value. The methods for generating the data structures and translating those data structures into an impact value are described in detail hereinabove, and some additional examples are provided below in regard to FIGS. 14 and 15.

Within the environment, the various elements transmit, receive, and/or access agronomic data (also referred to as agricultural data) that describes information of a particular agronomic region at a specific time. The agronomic data may include information, such as, attributes of the field, environmental conditions, farming practice performed on the field, and the like. In some embodiments, the agronomic data may be made available in different formats (or methods).

In some embodiments, the computing device 1302 may receive the agronomic data from the user device 1308, for example, input by growers operating the agronomic regions. In some embodiments, the computing device 1302 may receive the agronomic data from the sensing device 1306, for example, via remote sensing (satellite, sensors, drones, etc.). In some embodiments, the computing device 1302 may receive the agronomic data from a data store 1304, for example, agronomic data platforms such as John Deere and Granular, and/or data supplied by agronomists, and/or data generated by remote sensors (such as aerial imagery, satellite derived data, farm machine data, soil sensors, etc.). Exemplary remote sensing algorithms are provided in Publication Nos. WO 2021/007352, WO 2021/041666, WO 2021/062147, and WO 2022/020448, which are hereby incorporated by reference.

In some embodiments, the training of the machine-learned models described herein (such as neural networks and other models referenced herein) include the performance of one or more non-mathematical operations or implementation of non-mathematical functions at least in part by a machine or computing system, examples of which include but are not limited to data loading operations, data storage operations, data toggling or modification operations, non-transitory computer-readable storage medium modification operations, metadata removal or data cleansing operations, data compression operations, image modification operations, noise application operations, noise removal operations, and the like. Accordingly, the training of the machine-learned models described herein may be based on or may involve mathematical concepts, but is not simply limited to the performance of a mathematical calculation, a mathematical operation, or an act of calculating a variable or number using mathematical methods.

Likewise, it should be noted that the training of the models described herein cannot be practically performed in the human mind alone. The models are innately complex including vast amounts of weights and parameters associated through one or more complex functions. Training and/or deployment of such models involves so great a number of operations that it is not feasibly performable by the human mind alone, nor with the assistance of pen and paper. In such embodiments, the operations may number in the hundreds, thousands, tens of thousands, hundreds of thousands, millions, billions, or trillions. Moreover, the training data may include hundreds, thousands, tens of thousands, hundreds of thousands, or millions of temperature measurements. Accordingly, such models are necessarily rooted in computer-technology for their implementation and use.

The data store 1304 includes memory or other storage media for storing various files and data which are accessible to the computing device 1302. The data stored in the data store 1304 includes agronomic data, data objects, experimental templates, experimental data objects, models, etc. In various embodiments, the data store 1304 may take different forms. In one embodiment, the data store 1304 is part of the computing device 1302. For example, the data store 1304 is part of the local storage (e.g., hard drive, memory card, data server room) of the computing device 1302. In some embodiments, the data store 1304 is a network-based storage server (e.g., a cloud server). The data store 1304 may be a third-party storage system/platform.

A data store 1304 may be used to store data generated within the environment 1300, data describing agronomic activity received or accessed from third party sources, data generated by the computing device 1302 or impact estimation module 1320. The data store 1304 includes non-transitory and non-volatile memory and may be an example of data store. The data store 1304 may include unstructured data, semi-structured data, and structured data. Unstructured data may include raw data, event data, documents, and files. Semi-structured data may include various artificial intelligence models, machine learning models, and probability processing models, photos, user data and analytics. Structured data may include data from a third-party repository with information on inputs, outputs, and environmental impacts associated with these activities. Various suitable data structures such as Structured Query Language (SQL), other relational database structures, and/or NoSQL that uses key-value pairs, wide columns, graphs, inversed indices, tabular stores, or resource description framework (RDF) may be used in the data store 1304. In some embodiments, the computing device 1302 may include a database 1310 which includes agronomic data, data objects, experimental templates, experimental data objects, models, etc. stored in a manner similar to the database 1310.

The sensing device 1306 collects/observes agronomic data for a particular agronomic region at a time or within a time window. In some embodiments, the sensing device 1306 may include one or more sensors, such as, soil probes, land-based vehicles (e.g., tractors, planters, trucks, robots), hand-held devices (e.g., a cell phones, cameras, spectrophotometers), drones, airplanes, and satellites. In some embodiments, the sensing device 1306 includes a “field sensor” operated within a field boundary, for example, a soil moisture sensor, a flux tower (for example, a micrometeorological tower to measure the exchanges of carbon dioxide, water vapor, and energy between the biosphere and atmosphere), a soil temperature sensor, an air temperature sensor, a pH sensor, a nitrogen sensor, an irrigation system, a tractor, a robot, a vehicle, etc. In some embodiments, preliminary field data are automatically populated based on average practices and average practice dates within a region (for example as detected based on current season or historical remote sensing data analysis).

The user device 1308 is a computing device that is used by a user. A user may use the user device 1308 to communicate with the computing device 1302 and performs ecosystem management related operations. In some embodiments, a user device 1308 may include one or more applications and interfaces that may display visual elements of the applications. In some embodiments, preliminary data may be verified by input received from a farmer's user device 1308. For example, preliminary data may be presented and verified within a graphical user interface of a farmer's user device 1308. In some implementations, preliminary data may be verified by location and or accelerometer data or other data collected from a user device 1308. For example, a harvest practice identified by remote sensing data may be confirmed where machine data corresponding the typical engine speed of a harvester is recorded between the periodic images within a remote sensing time series collected from a satellite, where the first of that time series period does not indicate harvest has occurred and the next image indicates that harvest has occurred or is in progress.

The user device 1308 may be any computing device. Examples of such user device 1308 include personal computers (PC), desktop computers, laptop computers, tablets (e.g., iPADs), smartphones, wearable electronic devices such as smartwatches, farm equipment such as a drone or tractor, or any other suitable electronic devices. Other data collected from a user device may include a machine data (such as engine rpm, fuel level, location, machine hours, and changes in the same), input usage (for example, amounts and types of seeds, fertilizers, chemicals, water, applied), imagery and sensor data (for example, photographs, videos, LiDAR, infrared).

The network 1309 provides connections to the components of the ecosystem management environment 1300 through one or more sub-networks, which may include any combination of local area and/or wide area networks, using both wired and/or wireless communication systems. In one embodiment, a network 1309 uses standard communications technologies and/or protocols. For example, a network 1309 may include communication links using technologies such as Ethernet, 802.11, worldwide interoperability for microwave access (WiMAX), 3G, 4G, Long Term Evolution (LTE), 5G, code division multiple access (CDMA), digital subscriber line (DSL), etc. Examples of network protocols used for communicating via the network 1309 include multiprotocol label switching (MPLS), transmission control protocol/Internet protocol (TCP/IP), hypertext transport protocol (HTTP), simple mail transfer protocol (SMTP), and file transfer protocol (FTP).

Data exchanged over a network 1309 may be represented using any suitable format, such as hypertext markup language (HTML), extensible markup language (XML), JavaScript object notation (JSON), structured query language (SQL). In some embodiments, some of the communication links of a network 1309 may be encrypted using any suitable technique or techniques such as secure sockets layer (SSL), transport layer security (TLS), virtual private networks (VPNs), Internet Protocol security (IPsec), etc. The network 1309 also includes links and packet switching networks such as the Internet. In some embodiments, a data store belongs to part of the internal computing system of a server (e.g., the data store 1304 may be part of the computing device 1302). In such cases, the network 1309 may be a local network that enables the server to communicate with the rest of the components.

### Impact Estimation Module

FIG. 14 is a block diagram illustrating an impact estimation module, according to embodiments of the present disclosure. In various embodiments, the impact estimation module 1320 includes a precomputation module 1322 and a point estimation module 1324, but may include fewer or additional components. The impact estimation module 1320 also may include different components. The functions of various components in the impact estimation module 1320 may be distributed in a different manner than described below. Moreover, while each of the components in FIG. 14 may be described in a singular form, the components may be present in plurality.

The components of the impact estimation module 1320 may be embodied as modules that include software (e.g., program code including instructions) that is stored on an electronic medium (e.g., memory) and executable by a processing system (e.g., one or more general processors). The components also could be embodied in hardware, e.g., field-programmable gate arrays (FPGAs) and/or application-specific integrated circuits (ASICs), that may include circuits alone or circuits in combination with firmware and/or software.

At a high level, the impact estimation module 1320 receives a request to determine an aggregated impact value for an agronomic event. The aggregated impact value may be the impact value for, e.g., an agronomic region, an agronomic product, an agronomic producer, etc. To generate the impact value, the impact estimation module 1322 inputs agronomic data describing one or more agronomic events into one or more models, and the one or more model output the aggregated impact value for the agronomic event.

Moving to a greater level of detail, the impact estimation module 1320 includes a point estimation module 1324. The point estimation module 1324 generates an aggregated impact value for an agronomic event. The impact value may be for an agronomic region, an agronomic product, an agronomic process, an agronomic producer, etc. For example, the point estimation module 1324 may generate a prediction for the carbon emissions (e.g., impact value) of performing a fertilization action (e.g., agronomic activity) in a specific field (e.g., a point estimate).

To do so, the point estimation module 1324 can input data representing an agronomic activity. Oftentimes, the input agronomic data corresponds to an agronomic region such that the determined impact value represents that agronomic region. The data may be, e.g., data received from a user of a client device 1308, one or more sensing devices 1306, and/or the data store 1304. For example, the point estimation module 1324 may input data including a representation of a farmer's input of his field activities, data representing agronomic actions in a field determined from a satellite, and/or data representing previously measured and stored weather conditions for an agronomic season in the agronomic region. Other data is also possible.

The point estimation module 1324 can decompose received data representing an agronomic event into a series of agronomic activities. An agronomic activity is some agronomic action taken that constitutes, in whole or in part, the agronomic event. For instance, for the agronomic event of “tilling the field” the agronomic activities may include obtaining the machine, obtaining the fuel, performing the tilling, etc. The point estimation module 1324 may analyze the various data to determine quantitatively (e.g., an amount of fertilizer applied) or qualitatively (e.g., whether fertilizer was applied) describe which, and to what extent, various agronomic activities for the agronomic event occurred.

Further, the point estimation module 1324 may generate a reference data object representing the series of agronomic activities (e.g., a demand vector). In an example, the reference data object has a standard format. For instance, the reference data object may be a data vector having a particular size (e.g., specific number of rows and/or columns). Moreover, each entry in the reference data object may correspond to a reference activity. A reference activity is, for example, a standardized activity in the reference data object that constitutes the agronomic event.

The point estimation module 1324 may therefore map any number the agronomic activities to any number of the reference activities. In doing so, the point estimation module 1324 may combine, modify, scale, etc. any of the quantitative or qualitative representations of the agronomic activities corresponding to the agronomic event to the reference activities. For example, the point estimation module 1324 may map three of the agronomic activities to a single reference activity in the reference data object and scale the representation to account for the combination. Additionally, the point estimation module 1324 may tailor the reference data object for the impact value desired. For example, the data object may be structured to provide an impact value for a field, a product, a producer, etc.

The point estimation module 1324 may access a pre-computed translation array corresponding to the agronomic activity. A translation array typically includes one or more translation matrices. A translation array (and its constituent matrices) is a data object that maps elementary and/or intermediate events corresponding to an agronomic event to the ecosystem impact for that event. For example, if the agronomic event is a tilling event in a field, the translation matrices for tilling the field may quantify the various elementary and intermediate product flows corresponding to the tilling event. In other words, the translation matrices include various precalculated impact factors for the various activities in an agronomic event. Using the context above, translation matrix or matrices may be, e.g., the A matrix, the B matrix, TRACI impact factors, or some translation, modification, or inverse of those matrices, as a translation matrix or matrices. Moreover, a translation array may be any combination of those translation matrices, such as, e.g., a TRACI impact vector, the inverse of the A matrix, and the B matrix.

The point estimation module 1324 may determine an impact value using the reference data object and the pre-computed translation array. To do so, the point estimation module 1324 may multiply the pre-computed translation array (including its constituent matrices) and the reference data object, and sum the elements in the resulting data vector. The resulting impact value provides an estimation of impact of an agronomic activity or agronomic event in the field.

In an embodiment, the point estimation module 1324 may be implemented as an input output model. The input output model takes as input an agronomic region and an agronomic activity and outputs the impact value for that agronomic region. Other models are also possible.

As described above, generating translation matrices (e.g., A Matrix, B Matrix, TRACI factors) for many fields across many agronomic activities is a challenging process. To more efficiently and more economically provide impact values for an agronomic activity, the impact estimation module includes a precomputation module 1322. The precomputation module 1322 pre-generates matrices for a translation array such as, e.g., an A matrix, a B matrix, a TRACI impact matrix, and/or some translation, modification, and/or inverse of those matrices.

In some cases, the precomputation module 1450 may generate a translation array that corresponds to each agronomic event. For instance, the precomputation module 1322 may generate one or more translation matrices for a translation array corresponding to a tilling agronomic event, a harvesting agronomic event, a fertilizing agronomic event, an irrigation agronomic event, etc. Other translation arrays are also possible.

Additionally, when generating translation matrices for translation array, each generated translation matrix may be structured in a manner that accounts for the data structure of an agronomic event. Each agronomic event, as described above, may be represented by a series of agronomic activities—e.g., the agronomic event of “irrigation” may include agronomic activities such as, production of chemicals, transportation emissions from production market, diesel production (application), direct combustion of diesel (application), production of tractor and equipment, etc. Each of these agronomic activities of the agronomic event may be mapped to a standardized series of reference activities as described above. Accordingly, each of the translation matrices may be structured such that each element in a translation matrix or matrices correspond to the appropriate elements in a reference data object. In short, the reference data object and translation data matrices are encoded into a standard format such that input output model can interchange the matrices and data objects, as needed, without the needing to recompute the matrices.

As stated above, a translation array is precomputed. Precomputed, in this sense, indicates that each element in each translation matrix of a translation array is precomputed before the point estimation module 1324 calculates an aggregated impact value for an agronomic region. In more detail, the precomputation module 1322 pre-calculates various weights and coefficients for various elementary, intermediate, and TRACI impact factors corresponding to elements of a reference data object representing an agronomic event. The elements, in aggregate, provide a probabilistic representation of an ecosystem impact by an agronomic event in an agronomic region. In other words, each element in a translation matrix is a precalculated coefficient corresponding to an impact factor of a particular data flow between elementary exchanges, intermediate exchanges, TRACI impact factors, and a representation of an agronomic event. The precomputation module 1322 stores the translation array (e.g., a matrix or matrices) for each agronomic event in the database 1310.

As described above, to generate a translation array, the precomputation module 1322 runs a large number or Monte Carlo simulations (e.g., 100, 200, 500, 1,000, etc.) to estimate the impact factor for process flows between elementary and intermediate exchanges for an agronomic event (e.g., using an ecoinvent database stored in the datastore 1304). That is, the precomputation module 1322 creates a random or pseudo random simulated environment for an agronomic event and determines an impact value for the agronomic event using the various data flows through the elementary and intermediate exchanges using the simulated environment. Accordingly, the precomputation module 1322 can generate one or more translation matrices for each agronomic event that represents an aggregation of a large number of Monte Carlo simulations. This methodology prevents, e.g., a user device 1308 from executing a large number of Monte Carlo simulations each time prediction for an impact value for an agronomic event is requested.

Additionally, the precomputation module 1322 may generate translation arrays for each agronomic event that accounts for variance in the Monte Carlo simulations (e.g., error-aware translation arrays). In some cases, the precomputation module 1322 may account for variance in a manner that considers the data flows for the particular agronomic event. In effect, accounting for variation improves the determination capacity of the impact estimation module 1320 by accounting for the randomness inherent to Monte Carlo simulations. To do so, the precomputation module 1322 may record the output of each Monte Carlo simulation for a given agronomic event. The precomputation module 1322 may then analyze various correspondences, correlations, variances, standard deviations, etc. inherent in the recorded outputs and adjust the impact factors for the translation matrices for that impact factor accordingly. There are many methods for accounting for the variations, many of which are described hereinabove.

To illustrate the functionality of the impact estimation module 1320, FIG. 15 illustrates a workflow diagram for generating an aggregated impact value for an agronomic event, in accordance with one or more embodiments.

The computing device (e.g., computing device 1302) generates a number of translation arrays. Each translation array includes one or more translation matrices. Each translation array corresponds to an agronomic activity (e.g., A matrix, B matrix, etc.). Moreover, each translation matrix (and the translation array in aggregate) is structured such that it corresponds to a reference data object representing the agronomic event. In some cases, this can indicate that the translation matrices correspond to reference activities that, in aggregate, represent the agronomic event. Additionally, each of the translation arrays are generated to account for variance in the Monte-Carlo simulations employed to generate the translation matrices.

The computing device ingests 1502 data representing one or more agronomic events. The data may be received from a user device (e.g., user device 1308), a data store (e.g., data store 1304), and/or a sensing device (e.g., sensing device 1306) in a network environment (e.g., environment 1300).

The computing device applies 1504 an impact prediction model to the ingested data to generate the aggregated impact value. The impact prediction model may be an input output model.

The impact prediction model decomposes 1506 the one or more agronomic events into a series of agronomic activities. To do so, the computing device may apply various models to the ingested agronomic data, and/or perform various functions on the agronomic data to determine the series of agronomic activities representing the agronomic event.

The impact prediction model encodes 1508 the series of agronomic activities into a reference data object. The reference data object is structured to generate an aggregated impact factor for the agronomic activity in the agronomic region. Additionally, each element in the reference data object corresponds to a series of reference activities. Each of the references activities corresponds to one or more of the series of activities representing the agronomic activity. The reference data object, as a whole, is created to generate a normalized representation of an agronomic activity given the variability of the ingested data representing an agronomic activity.

The impact prediction model accesses 1510 a precomputed translation array corresponding to the agronomic event encoded into the reference data object. The translation data array includes one or more translation matrices (e.g., A Matrix, B Matrix, etc.). The matrices in the precomputed translation array 1512 include precalculated impact factors corresponding to each reference activity in the reference data object. Additionally, the precalculated impact factors are generated based 1514 on a set of error-aware Monte-Carlo simulations for the agronomic activity (e.g., the impact factors in the matrices of the translation array are computed to account for variance in the Monte-Carlo simulations).

The impact prediction model determines 1516 an impact value for each activity in the series of activities using the encoded reference data object and the precomputed translation array.

The impact prediction model determines 1518 an impact value for the one or more agronomic events by aggregating each impact value for the series of activities. Optionally the output impact value is scaled based on the material flow of a particular region and time. For example, urea was applied to field A on date Y at a rate of 180 pounds/acre, while urea was applied to field B at a rate of 230 pounds/acre on date Z. In this example the impact values for urea application events on field A and field B would be scaled according to their relative usage of urea Optionally, the output impact value is returned based on a relevant unit for the agronomic event, for example, an impact value for an agronomic event of urea application may be reported as a quantity of emissions (for example in metric tons CO2 equivalent) per pound of urea.

The impact prediction model 1520 outputs the aggregated impact value. For example, the impact prediction model may output the aggregated impact value to a user device for display on that user device.

### Additional Configurations

In some example embodiments, the computing device 1302 determining an aggregate impact value for an agronomic event in an agronomic region may enable additional functionality within the environment 1300.

For example, in an example embodiment, the computing device 1302 may utilize the generated aggregate impact value to make one or more inferences about an agronomic region. An inference in this context is using data describing one agronomic region within the ecosystem to infer additional information for that agronomic region or a different agronomic region. For example, the aggregate impact value for a region may be extrapolated to other regions that are characterized as similar based on a variety of characteristics (e.g., position in space, time, field conditions, similarity of agronomic events, etc.).

In an example embodiment, the computing device may combine the generated agronomic impact value for the region with additional agronomic data describing, determined for, derived from, extrapolated to, the agronomic region to generate a summary of agronomic data for the agronomic regions. For example, remote sensing inferences such as field boundaries within the region, crop types, management practices (tillage, cover crop, planting, harvesting, grazing) and the associated dates of management events may be associated with a summary for the agronomic region. Additionally, data collected directly from farmers or from regional surveys, historical surveys, academic literature etc. can be associated with the summary for the agronomic region. Any aspect of the summary may be displayed for a user of a user device 1308. For example, the user device 1308 may display a map with the agronomic region and one or more data layers on the map. The data layers may be representations of any of the information included in the summary. The field level information may be shown within the field boundaries drawn on the map using numerical values, intensity overlays, etc.

In an example embodiment, impact values may be generated automatically upon detection of a change associated with an agronomic event, or geographic region of interest. For example, one or more regions (for example, fields) may be monitored over time (for example, via remote sensors, e.g. satellite imagery, field-based sensors, farm machine-based sensors), and upon detection of a presence, absence (for example, lack of planting, irrigation, and or harvesting), or change in an agronomic event (for example, a reduction in a rate water applied during irrigation), an updated impact value is generated automatically without human intervention. Similarly, an updated impact value may be generated automatically upon a change in a geographic region of interest, for example, upon the addition, removal, or change in area of one or more fields. In some examples, a change in a geographic region of interest may be detected based on monitoring of field boundaries generated from satellite imagery time series.

The methods for generating an impact value described herein may also be used to enable a user to test alternative scenarios, for example to assess the impact of a change of one or more farming operations, to compare agricultural products sourced from different regions and or different crop production seasons, to assess the impact of weather events, etc.

### ADDITIONAL CONSIDERATIONS

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method for generating an aggregated impact value, comprising:
ingesting, at a computing device, data representing one or more agronomic event; and
applying, at the computing device an impact prediction model to the one or more agronomic event, the impact prediction model:
decomposing, based on the data, the one or more agronomic events into a series of agronomic activities;
encoding the series of agronomic activities into a reference data object comprising a series of reference activities corresponding to the series of activities;
accessing a precomputed translation array corresponding to the reference data object, wherein:
the precomputed translation array comprises precalculated impact factors corresponding to each reference activity in the series of reference activities, and
the precalculated impact factors are generated based on a plurality of error-aware Monte-Carlo simulations;
determining, for each activity in the series of activities, an impact value using the encoded reference data object and the precomputed translation array;
determining an impact value for the one or more agronomic event by aggregating the impact value for the series of activities; and
outputting the aggregated impact value.

2. The method of claim 1, wherein decomposing the one or more agronomic event into a series of agronomic activities comprises:
populating one or more missing activity for the one or more agronomic events.

3. The method of claim 1, wherein decomposing the one or more agronomic event into a series of agronomic activities comprises:
mapping the one or more agronomic event to a reference activity in the series of reference activities.

4. The method of claim 1, wherein the impact value is an emissions output.

5. The method of claim 1, wherein the precomputed translation array is generated by running an impact model on a database accessed from a datastore.

6. The method of claim 5, wherein the impact model is an emissions model.

7. The method of claim 1, encoding the series of agronomic activities into a reference data object comprises:
generating elements in the reference data object representing the series of agronomic activities; and
weighting the elements based on attributes associated with the agronomic event.

8. The method of claim 7, wherein the weighted elements associated representing the series of agronomic activities comprises non-linear activities and co-variance factors.

9. The method of claim 1, wherein precomputed translation array comprises uncertainty values, and wherein aggregating the impact value for each agronomic event comprises aggregating the uncertainty values.

10. The method of claim 1, further comprising:
for each agronomic event of a plurality of agronomic events, generating one or more matrices configured to aggregate the impact of the agronomic event; and
selecting one or more of the generated matrices for the agronomic event as the translation array.

11. The method of claim 10, further comprising:
reading a series of activity definitions and uncertainty distributions for the one or more agronomic event;
generating a unique model ID to identify a set of randomly-sampled matrices;
generating a set of randomly sampled matrices; and
saving the set of randomly sampled matrices for reuse.

12. The method of claim 1, wherein the impact value for each agronomic event comprises a pre-field emissions score.

13. The method of claim 1, wherein the impact value for each agronomic event comprises on-field emissions scores.

14. The method of claim 1, further comprising receiving emissions values for additional agronomic events from alternative emissions models.

15. The method of claim 1, wherein the agronomic event includes at least one of fertilization, tillage, grazing, irrigation, planting, and/or harvesting.

16. The method of claim 1, wherein the one or more agronomic event is measured over a partial crop rotation or a complete crop rotation.

17. The method of claim 1, wherein each set of reference activities has an associated frequency.

18. The method of claim 1, further comprising:
generating the precomputed translation array by:
reading in an activity information as a CSV;
generating a unique model identification to identify a set of randomly-sampled matrices;
saving the randomly-sampled matrices for reuse; and
providing a randomly sampled matrix of the randomly sampled matrices as a precomputed reference matrix.

19. The method of claim 1, wherein the data representing agronomic events comprise remote sensing data.

20. The method of claim 1, further comprising monitoring remote sensing data corresponding to one or more geographic regions, detecting a presence, absence, or change in an agronomic event within the region based on the remote sensing data, and automatically applying the impact prediction model.

21. A system comprising:
one or more processors;
a non-transitory computer-readable storage medium comprising computer program instructions for generating an aggregated impact value, the computer program instructions, when executed by the one or more processors, causing the one or more processors to:
applying, at the computing device an impact prediction model to the one or more agronomic event, the impact prediction model:
decompose, based on the data, the one or more agronomic events into a series of agronomic activities;
encode the series of agronomic activities into a reference data object comprising a series of reference activities corresponding to the series of activities;
access a precomputed translation array corresponding to the reference data object, wherein:
the precomputed translation array comprises precalculated impact factors corresponding to each reference activity in the series of reference activities, and
the precalculated impact factors are generated based on a plurality of error-aware Monte-Carlo simulations;
determine, for each activity in the series of activities, an impact value using the encoded reference data object and the precomputed translation array;
determine an impact value for the one or more agronomic event by aggregating the impact value for the series of activities; and
output the aggregated impact value.

22. A non-transitory computer-readable storage medium comprising computer program instructions for generating an aggregated impact value, the computer program instructions, when executed by the one or more processors, causing the one or more processors to:
applying, at the computing device an impact prediction model to the one or more agronomic event, the impact prediction model:
decompose, based on the data, the one or more agronomic events into a series of agronomic activities;
encode the series of agronomic activities into a reference data object comprising a series of reference activities corresponding to the series of activities;
access a precomputed translation array corresponding to the reference data object, wherein:
the precomputed translation array comprises precalculated impact factors corresponding to each reference activity in the series of reference activities, and
the precalculated impact factors are generated based on a plurality of error-aware Monte-Carlo simulations;
determine, for each activity in the series of activities, an impact value using the encoded reference data object and the precomputed translation array;
determine an impact value for the one or more agronomic event by aggregating the impact value for the series of activities; and
output the aggregated impact value.
